(19) United States
(12) Patent Application Publication
(10) Pub. No.: US 2024/0272551 A1
(43) Pub. Date: Aug. 15, 2024

(54) NEGATIVE-TYPE PHOTOSENSITIVE POLYMER, POLYMER SOLUTION, NEGATIVE-TYPE PHOTOSENSITIVE RESIN COMPOSITION, CURED FILM, AND SEMICONDUCTOR DEVICE

(71) Applicant: SUMITOMO BAKELITE CO., LTD., Shinagawa-ku, Tokyo (JP)

(72) Inventors: Keita Imai, Tokyo (JP); Akihiko Otoguro, Tokyo (JP)

(21) Appl. No.: 18/566,685

(22) PCT Filed: Jun. 22, 2022
(86) PCT No.: PCT/JP2022/024842

§ 371 Date: Dec. 4, 2023

(30) Foreign Application Priority Data
Jun. 25, 2021 (JP) 2021-105687
Feb. 10, 2022 (JP) 2022-019325

(51) Int. Cl. G03F 7/038; G03F 7/004

(52) U.S. Cl. CPC G03F 7/038; G03F 7/0045; G03F 7/0048

(57) ABSTRACT

A negative-type photosensitive polymer of the present invention is a solvent-soluble negative-type photosensitive polymer which has a structural unit containing an imide ring and contains a group represented by General Formula (t) at at least one of both terminals, in which an average value of positive electric charges (δ+) of two carbonyl carbons of the imide ring is equal to or less than 0.095 as calculated by a charge equilibration method.

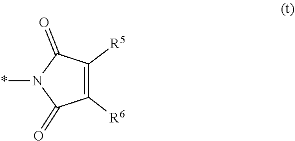

### TECHNICAL FIELD

The present invention relates to a negative-type photosensitive polymer, a polymer solution, a negative-type photosensitive resin composition, a cured film, and a semiconductor device.

### BACKGROUND ART

Polyimide resins have a high level of mechanical strength, heat resistance, insulation, and solvent resistance, and thus have been widely used as a thin film for a protective material, an insulating material, an electronic material such as a color filter, and the like in liquid crystal display devices and semiconductors.

Patent Document 1 discloses a photosensitive composition containing a polyimide having a dimethylmaleimide group at the terminal, a photoradical generator, a photoacid generator, and one or more crosslinking agents. In the Examples, a fluorine-containing compound is used as a main monomer component.

### RELATED DOCUMENT

### Patent Document

[Patent Document 1] International Publication No. WO2020/181021

### SUMMARY OF THE INVENTION

### Technical Problem

However, it was found that mechanical strength such as elongation is reduced by hydrolysis in the conventional polymer disclosed in Patent Document 1. In addition, a negative-type photosensitive polymer is also required to have excellent solubility in general solvents used in varnishes.

### Solution to Problem

The inventors of the present invention have found that, in a negative-type photosensitive polymer having a structural unit containing an imide ring and containing a predetermined group at a terminal, hydrolysis is inhibited when positive electric charges of carbonyl carbons of the imide ring are within a predetermined range, and thereby the present invention was completed.

In other words, the present invention can be described below.

[1] A solvent-soluble negative-type photosensitive polymer which has a structural unit containing an imide ring, the negative-type photosensitive polymer containing, at at least one of both terminals, a group represented by General Formula (t),
in which an average value of positive electric charges (δ+) of two carbonyl carbons of the imide ring is equal to or less than 0.095 as calculated by a charge equilibration method.

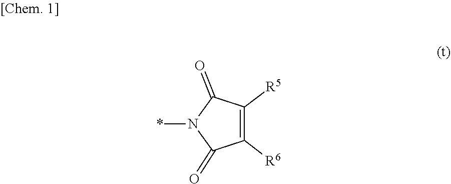

(In General Formula (t), R⁵ and R⁶ each independently represent a hydrogen atom or an alkyl group having 1 to 3 carbon atoms, provided that at least one is an alkyl group having 1 to 3 carbon atoms; and * represents a bonding site.)

[2] The negative-type photosensitive polymer according to [1], in which a fluorine atom is not contained in a molecular structure.

[3] The negative-type photosensitive polymer according to [1] or [2], in which the structural unit is represented by General Formula (1).

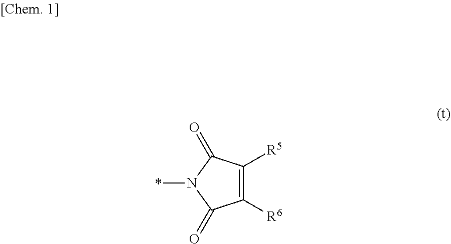

(In General Formula (1), X represents a divalent organic group including an aromatic group; A represents a ring structure having two carbons of the imide ring; and Q represents a divalent organic group.)

[4] The negative-type photosensitive polymer according to [3], further containing an electron-donating group at two ortho positions with respect to a carbon atom bonded to a nitrogen atom in General Formula (1), in which the aromatic group included in the divalent organic group as X in General Formula (1) is bonded to the nitrogen atom.

[5] The negative-type photosensitive polymer according to [3] or [4], in which X in General Formula (1) is a divalent group represented by General Formula (1a) or General Formula (1b).

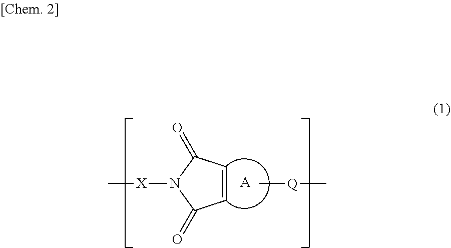

(In General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups; X¹ represents a single bond, —SO₂—, —C(═O)—, a linear or branched alkylene group having 1 to 5 carbon atoms, or a fluorenylene group; and * represents a bonding site, and
in General Formula (1b), R^{a} and R^{b} each independently represent a hydrogen atom, an alkyl group having 1 to 3 carbon atoms, or an alkoxy group having 1 to 3 carbon atoms, provided that a plurality of R^{a}'s may be the same as or different from each other, and a plurality of R^{b}'s may be the same as or different from each other; and * represents a bonding site.)

[6] The negative-type photosensitive polymer according to any one of [3] to [5], in which A in General Formula (1) is an aromatic ring.

[7] The negative-type photosensitive polymer according to any one of [3] to [6], in which Q in General Formula (1) is a divalent group containing an imide ring.

[8] The negative-type photosensitive polymer according to any one of [5] to [7], in which the structural unit represented by General Formula (1) includes a structural unit represented by General Formula (1-1).

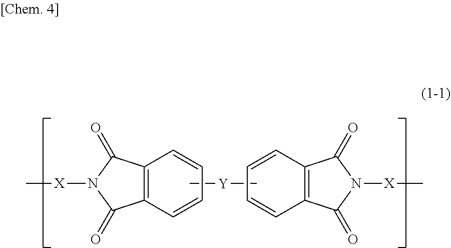

(In General Formula (1-1), X is the divalent group represented by General Formula (1a) or General Formula (1b); and Y is a divalent organic group.)

[9] The negative-type photosensitive polymer according to [8], in which Y in General Formula (1-1) is a divalent organic group selected from General Formula (a1-1), General Formula (a1-2), General Formula (a1-3), and General Formula (a1-4).

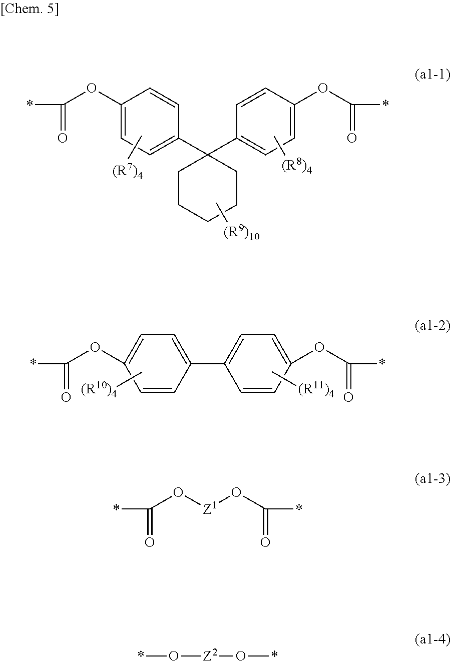

(In General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other; R⁹ represents a hydrogen atom, an alkyl group having 1 to 3 carbon atoms, or an alkoxy group having 1 to 3 carbon atoms, provided that a plurality of R⁹'s may be the same as or different from each other; and * represents a bonding site,
in General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other; and * represents a bonding site,
in General Formula (a1-3), Z¹ represents an alkylene group having 1 to 5 carbon atoms or a divalent aromatic group; and * represents a bonding site, and
in General Formula (a1-4), Z² represents a divalent aromatic group; and * represents a bonding site.)

[10] The negative-type photosensitive polymer according to [8] or [9], further containing, at at least one of both of the terminals, a group represented by General Formula (t-1).

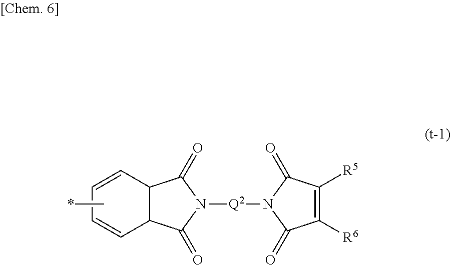

(In General Formula (t-1), R⁵ and R⁶ each independently represent a hydrogen atom or an alkyl group having 1 to 3 carbon atoms, provided that at least one is an alkyl group having 1 to 3 carbon atoms; Q² represents a divalent organic group; and * represents a bonding site.)

[11] The negative-type photosensitive polymer according to any one of [1] to [10], in which equal to or more than 5% by mass of the negative-type photosensitive polymer is dissolved in a solvent selected from N-methyl-2-pyrrolidone, N-ethyl-2-pyrrolidone, γ-butyrolactone (GBL), and cyclopentanone.

[12] The negative-type photosensitive polymer according to any one of [1] to [11], in which equal to or more than 5% by mass of the negative-type photosensitive polymer is dissolved in cyclopentanone.

[13] The negative-type photosensitive polymer according to any one of [1] to [12], in which a reduction rate of a weight-average molecular weight measured under the following condition is equal to or less than 15%.

### (Condition)

When 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression.

Expression: [(weight-average molecular weight before test−weight-average molecular weight after test)/weight-average molecular weight before test]×100

[14] A polymer solution containing the negative-type photosensitive polymer according to any one of [1] to [13].

[15] A negative-type photosensitive resin composition containing:
(A) the negative-type photosensitive polymer according to any one of [1] to [13];
(B) a crosslinking agent (B) (excluding the polyimide (A)) having a substituted or unsubstituted maleimide group; and
(C) a photosensitizer.

[16] The negative-type photosensitive resin composition according to [15], in which the crosslinking agent (B) has a structural unit represented by General Formula (b).

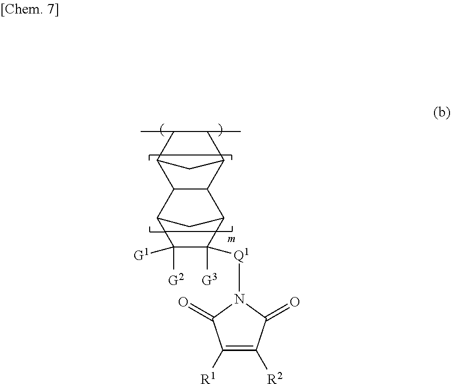

(In General Formula (b), R¹ and R² each independently represent a hydrogen atom or an alkyl group having 1 to 3 carbon atoms; Q¹ represents a single bond or a divalent organic group; G¹, G², and G³ each independently represent a hydrogen atom or a substituted or unsubstituted hydrocarbon group having 1 to 30 carbon atoms; and m is 0, 1, or 2.)

[17] The negative-type photosensitive resin composition according to [16], in which the divalent organic group as Q¹ is an alkylene group having 1 to 8 carbon atoms or a (poly)alkylene glycol chain.

[18] A cured film formed from a cured product of the negative-type photosensitive resin composition according to any one of [15] to [17].

[19] A semiconductor device including a resin film including a cured product of the negative-type photosensitive resin composition according to any one of [15] to [17].

In the present invention, the term “positive electric charge (δ+)” means that the electric charges on atoms in a molecule are calculated by a charge equilibration method (Charge (Q) Equilibration (Eq): QEq) to denote a positive electric charge on a predetermined atom with delta plus (δ+).

The above-mentioned charge equilibration method is as follows.

When atoms form a bond, the electron density is changed until the electronegativities are equal to each other (until a balance is achieved). First, electric charges on all atoms in a molecule start from 0, and electrons flow from atoms with a low electronegativity to atoms with a high electronegativity. When electrons are stored on the atom, the electronegativity is reduced, and when a balance is achieved, the electronegativities of each atom become equal to each other, and the flow of electrons is stopped. In the charge equilibration method, the above-described repeating calculation is carried out to calculate the electric charges on the atom in the molecule to denote the positive electric charge of a predetermined atom with delta plus (δ+) and denote the negative electric charge of a predetermined atom with delta minus (δ−).

In addition, the negative-type photosensitive polymer of the present invention is dissolved in a solvent and used as a varnish. The term “solvent-soluble” means soluble in any of general solvents used in varnishes. Examples of the general solvents include N-methyl-2-pyrrolidone, N-ethyl-2-pyrrolidone, γ-butyrolactone (GBL), and cyclopentanone.

The term “soluble” means that equal to or more than 5% by mass of the negative-type photosensitive polymer of the present invention is dissolved in 100% by mass of these predetermined solvents.

### Advantageous Effects of Invention

According to the present invention, it is possible to provide a negative-type photosensitive polymer, from which a cured product such as a film is obtained, and a negative-type photosensitive resin composition containing the polymer, provided that in the cured product such as a film, the solubility in organic solvents is excellent, and also, hydrolysis is inhibited, thereby minimizing a reduction in mechanical strength such as elongation.

### BRIEF DESCRIPTION OF THE DRAWINGS

FIG. 1 is a schematic cross-sectional view of a semiconductor device of the present embodiment.

### DESCRIPTION OF EMBODIMENTS

Hereinafter, embodiments of the present invention will be described with reference to drawings. In all the drawings, the same components are designated by the same reference numerals, and description thereof will not be repeated as appropriate. In addition, for example, “1 to 10” represents from “equal to or more than 1” and “equal to or less than 10” unless otherwise specified.

A solvent-soluble negative-type photosensitive polymer of the present embodiment has a structural unit containing an imide ring, and contains a group represented by General Formula (t) below at at least one of both terminals.

The average value of positive electric charges (δ+) of two carbonyl carbons of the above-mentioned imide ring is equal to or less than 0.095, preferably equal to or less than 0.094, more preferably equal to or less than 0.093, and further preferably equal to or less than 0.092 as calculated by a charge equilibration method.

Thus, it is possible to provide a cured product such as a film in which the solubility in organic solvents is excellent, and also, hydrolysis is inhibited, thereby minimizing a reduction in mechanical strength such as elongation.

In addition, the lower limit value of the average value of the positive electric charges (δ+) of two carbonyl carbons of the above-mentioned imide ring is not particularly limited, but is preferably equal to or more than 0.070, more preferably equal to or more than 0.080, and further preferably equal to or more than 0.085. When the average value is equal to or more than the lower limit value, it is thought that the coloration caused by an electric charge bias can be prevented, and it is thought that a decrease in sensitivity when the negative-type photosensitive polymer of the present embodiment is formed into a photosensitive resin composition can be minimized.

The upper limit value and the lower limit value can be arbitrarily combined.

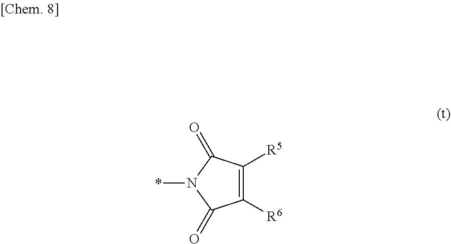

In General Formula (t), R⁵ and R⁶ each independently represent a hydrogen atom or an alkyl group having 1 to 3 carbon atoms. It is preferable that at least one of R⁵ and R⁶ be an alkyl group having 1 to 3 carbon atoms, and it is more preferable that both thereof be an alkyl group having 1 to 3 carbon atoms. From the viewpoint of the effects of the present invention, the alkyl group having 1 to 3 carbon atoms is preferably an alkyl group having 1 or 2 carbon atoms, and more preferably an alkyl group having 1 carbon atom. At least one of R⁵ and R⁶ is an alkyl group having 1 to 3 carbon atoms. * represents a bonding site.

According to the negative-type photosensitive polymer of the present embodiment, it is possible to provide a cured product such as a film in which the solubility in organic solvents is excellent, and also, hydrolysis is inhibited, thereby minimizing a reduction in mechanical strength such as elongation.

The solvent-soluble negative-type photosensitive polymer of the present embodiment may contain a fluorine atom in the molecular structure within a range not affecting the effects of the present invention as long as the above-mentioned average value of the positive electric charges (δ+) of carbonyl carbons is within a predetermined range, but it is preferable that a fluorine atom having a strong electron-withdrawing character be not contained in the molecular structure.

The structural unit containing the imide ring and included the solvent-soluble negative-type photosensitive polymer can be represented by General Formula (1) below.

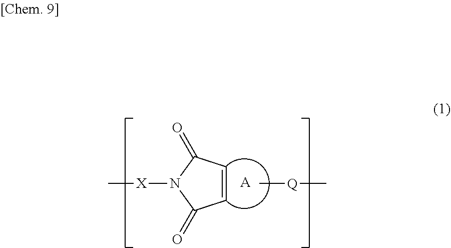

A in General Formula (1) represents a ring structure having two carbons of an imide ring, and is preferably an aromatic ring such as a benzene ring or a naphthalene ring.

Q in General Formula (1) represents a divalent organic group, and is preferably a divalent group containing an imide ring.

In General Formula (1), X represents a divalent organic group including an aromatic group.

The aromatic group included in the divalent organic group as X in General Formula (1) above is preferably bonded to a nitrogen atom in General Formula (1) above. The two ortho positions with respect to the carbon atom of the aromatic group bonded to the above-mentioned nitrogen atom more preferably have an electron-donating group, and further preferably have an asymmetrical electron-donating group. Examples of the electron-donating groups include a hydrogen atom, an alkyl group having 1 to 3 carbon atoms, and an alkoxy group having 1 to 3 carbon atoms.

Examples of the above-mentioned divalent organic groups as X include a divalent group represented by General Formula (1a) below or General Formula (1b) below. The negative-type photosensitive polymer having the structural unit in which X above is these groups has a high glass transition temperature, a low coefficient of linear expansion, and excellent mechanical strength, and thus can provide a molded product having excellent reliability.

X can include at least one divalent group represented by General Formula (1a) or at least one divalent group represented by General Formula (1b), and can also include a combination of these groups.

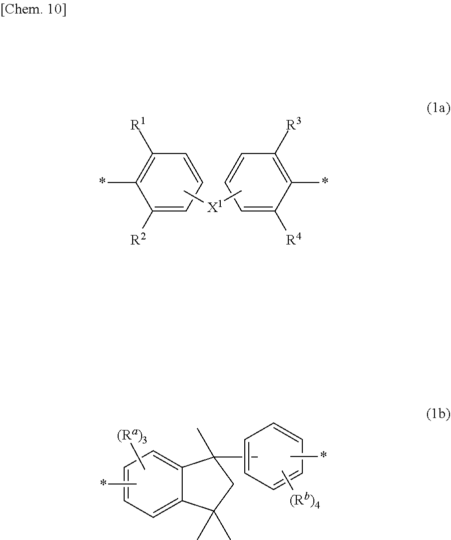

In General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups.

X¹ represents a single bond, —SO₂—, —C(═O)—, a linear or branched alkylene group having 1 to 5 carbon atoms, or a fluorenylene group. * represents a bonding site.

In General Formula (1b), R^{a} and R^{b} each independently represent a hydrogen atom, an alkyl group having 1 to 3 carbon atoms, or an alkoxy group having 1 to 3 carbon atoms. Provided that a plurality of R^{a}'s may be the same as or different from each other, and a plurality of R^{b}'s may be the same as or different from each other. * represents a bonding site.

The condition under which two ortho positions (R¹ and R² (or R³ and R⁴)) with respect to the carbon atom of a benzene ring directly bonded to the nitrogen atom of General Formula (1) have a predetermined electron-donating group is preferable from the viewpoint of the effects of the present invention. X in General Formula (1) above is more preferably the divalent group represented by General Formula (1a) above.

Specifically, the structural unit represented by General Formula (1) above preferably includes a structural unit represented by General Formula (1-1) below.

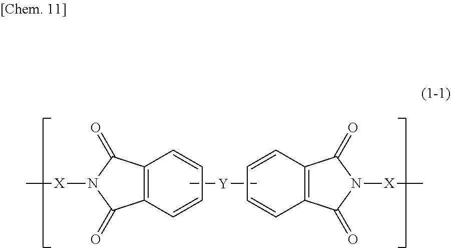

Examples of X in General Formula (1-1) include a divalent group represented by General Formula (1a) above or General Formula (1b) above.

Y in General Formula (1-1) is a divalent organic group.

The divalent organic group can be selected from General Formula (a1-1) below, General Formula (a1-2) below, General Formula (a1-3) below, and General Formula (a1-4) below.

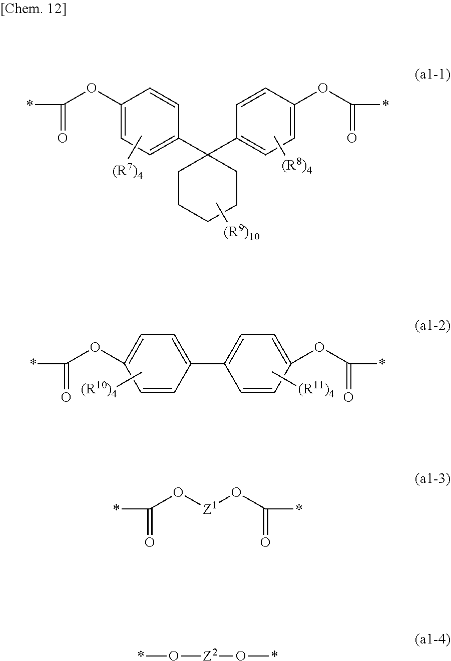

In General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other.

From the viewpoint of the effects of the present invention, R⁷ and R⁸ are preferably a hydrogen atom or an alkyl group having 1 to 3 carbon atoms, and more preferably a hydrogen atom.

R⁹ represents a hydrogen atom, an alkyl group having 1 to 3 carbon atoms, or an alkoxy group having 1 to 3 carbon atoms, provided that a plurality of R⁹'s may be the same as or different from each other.

From the viewpoint of the effects of the present invention, R⁹ is preferably a hydrogen atom or an alkyl group having 1 to 3 carbon atoms, and more preferably a hydrogen atom.

* represents a bonding site.

In General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other.

From the viewpoint of the effects of the present invention, it is preferable that R¹⁰ and R¹¹ be a hydrogen atom or an alkyl group having 1 to 3 carbon atoms; it is more preferable that at least one of R¹⁰'s and at least one of R¹¹'s be an alkyl group having 1 to 3 carbon atoms; it is further preferable that three R¹⁰'s be an alkyl group having 1 to 3 carbon atoms and one R¹⁰ be a hydrogen atom, and that three R¹¹'s be an alkyl group having 1 to 3 carbon atoms and one R¹¹ be a hydrogen atom; and it is particularly preferable that three R¹⁰'s be a methyl group and one R¹⁰ be a hydrogen atom, and that three R¹¹'s be a methyl group and one R¹¹ be a hydrogen atom.

* represents a bonding site.

In General Formula (a1-3), Z¹ represents an alkylene group having 1 to 5 carbon atoms or a divalent aromatic group.

* represents a bonding site.

In General Formula (a1-4), Z² represents a divalent aromatic group, and is preferably a divalent benzene ring. * represents a bonding site.

The negative-type photosensitive polymer of the present embodiment can have at least one structural unit selected from a structural unit (1-1a) represented by General Formula (1-1a) below and a structural unit (1-1b) represented by General Formula (1-1b) below.

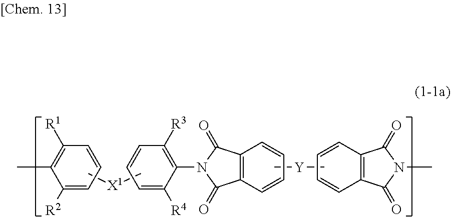

In General Formula (1-1a), R¹ to R⁴ and X¹ have the same definition as those in General Formula (1a), and Y has the same definition as that in General Formula (1-1).

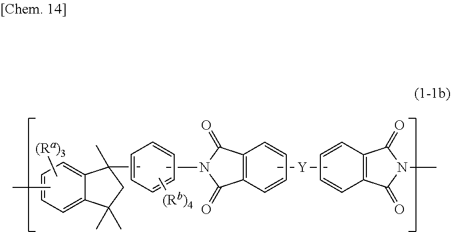

In General Formula (1-1b), R^{a} and R^{b} have the same definitions as those in General Formula (1b), and Y has the same definition as that in General Formula (1-1).

From the viewpoint of the effects of the present invention, the negative-type photosensitive polymer of the present embodiment preferably has a group t-1 represented by General Formula (t-1) below at at least one terminal of both terminals, preferably at both terminals.

When the negative-type photosensitive polymer has this terminal structure, a cured product having excellent mechanical strength can be obtained. Furthermore, because photodimerization is possible without causing a radical reaction, the polyimides (A) can be photopolymerized with each other, and the polyimide (A) and the crosslinking agent (B) to be described later can be photopolymerized, which makes mechanical strength excellent.

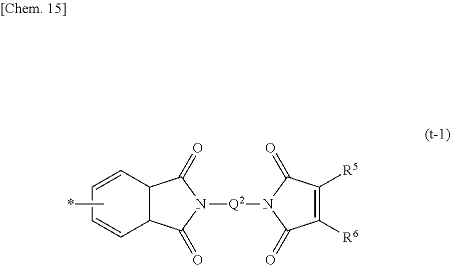

In General Formula (t-1), R⁵ and R⁶ each independently represent a hydrogen atom or an alkyl group having 1 to 3 carbon atoms. It is preferable that at least one of R⁵ and R⁶ be an alkyl group having 1 to 3 carbon atoms, and it is more preferable that both thereof be an alkyl group having 1 to 3 carbon atoms. From the viewpoint of the effects of the present invention, the alkyl group having 1 to 3 carbon atoms is preferably an alkyl group having 1 or 2 carbon atoms, and more preferably an alkyl group having 1 carbon atom. * represents a bonding site.

Q² represents a divalent organic group.

As the above-mentioned divalent organic group, a known organic group can be used within a range in which the effects of the present invention are exhibited. Examples thereof include the divalent organic group represented by General Formula (1a) above or General Formula (1b) above.

In addition, the terminal of the negative-type photosensitive polymer may have at least one group selected from a group u-1 represented by General Formula (u-1) below and a group u-2 represented by General Formula (u-2) below.

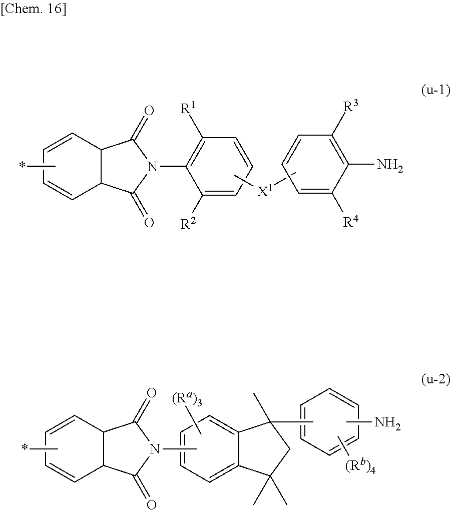

In General Formula (u-1), X¹ and R¹ to R⁴ have the same definitions as those in General Formula (1a).

In General Formula (u-2), R^{a} and R^{b} have the same definition as those in General Formula (1b).

When the negative-type photosensitive polymer has the above-mentioned group u-1 and/or the above-mentioned group u-2, the ratio (t-1)/[(t-1)+(u-1)+(u-2)] of the number of moles of the group t-1 to the total number of moles of the group t-1 and the group u-1 and/or the above-mentioned group u-2 is equal to or more than 0.5, preferably equal to or more than 0.55, and more preferably equal to or more than 0.6. In this range, the negative-type photosensitive polymer eluted by development can be reduced.

In the present embodiment, for example, in the negative-type photosensitive polymer having the structural unit represented by General Formula (1-1) above, the average value of the positive electric charges (δ+) of two carbonyl carbons of the imide ring is measured as follows.

The average value of δ+ of two carbonyl carbons of the imide ring contained in the compound represented by General Formula (1-1′) below, which is measured under the following condition, is calculated.

### [Condition]

The compound represented by General Formula (1-1′) above is measured by a charge equilibration method using soft HSPiP (ver. 5.3), and δ+ of two carbonyl carbons of the imide ring contained in the above-mentioned compound is averaged to obtain the average value.

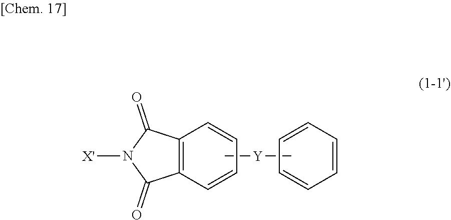

In General Formula (1-1′), Y has the same definition as that in General Formula (1-1). X¹ is a monovalent group represented by General Formula (1a-1) below or General Formula (1b-1) below.

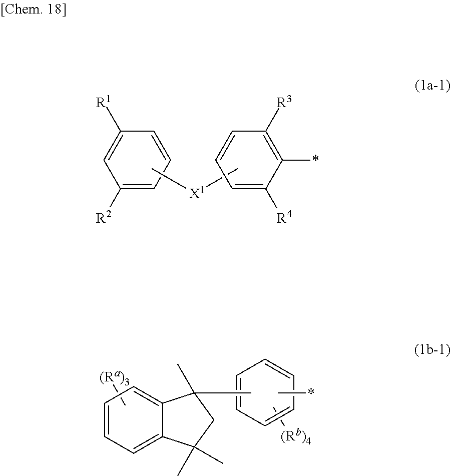

In General Formula (1a-1), R¹ to R⁴ and X¹ have the same definitions as those in General Formula (1a). * represents a bonding site. In General Formula (1b-1), R^{a} and R^{b} have the same definition as those in General Formula (1b). * represents a bonding site.

When the negative-type photosensitive polymer having the structural unit represented by General Formula (1-1) above has a plurality of groups as X, the average value of δ+ is calculated for each possible combination, and the weighted average is taken according to the charging amount to calculate the average value of the positive electric charges (δ+) of two carbonyl carbons of the imide ring.

Specifically, when the negative-type photosensitive polymer having the structural unit represented by General Formula (1-1) has the structural unit (1-1a) having the group of General Formula (1a) as X and the structural unit (1-1b) having the group of General Formula (1b) as X, the compound represented by General Formula (1-1′) above having the group of General Formula (1a-1) is measured by a charge equilibration method using soft HSPiP (ver. 5.3), and δ+ of two carbonyl carbons of the imide ring contained in the above-mentioned compound is averaged to obtain an average value (1). The compound represented by General Formula (1-1′) above having the group of General Formula (1b-1) is measured in the same manner, and δ+ of two carbonyl carbons of the imide ring contained in the above-mentioned compound is averaged to obtain an average value (2). In addition, when the total of the number of moles (1) of the structural unit (1-1a) and the number of moles (2) of the structural unit (1-1b) is set to 100, δ+ is calculated by the following expression.

$$Expression : [ average value ( 1 ) of δ + \times molar fraction ( 1 ) + average value ( 2 ) of δ + \times molar fraction ( 2 ) ] / 100$$

When the negative-type photosensitive polymer having the structural unit represented by General Formula (1-1) above has three or more groups as X, as in the same manner described above, the average value of δ+ is calculated for each possible combination, and the weighted average is taken according to the charging amount to calculate the average value of the positive electric charges (δ+) of two carbonyl carbons of the imide ring of the negative-type photosensitive polymer.

The weight-average molecular weight of the negative-type photosensitive polymer of the present embodiment is 25,000 to 200,000, preferably 30,000 to 150,000, and more preferably 40,000 to 100,000.

When the weight-average molecular weight is within the above-mentioned range, a glass transition temperature is high, a coefficient of linear expansion is low, and mechanical strength is excellent, and thus a molded product having excellent reliability can be obtained.

Since the hydrolysis is inhibited in the negative-type photosensitive polymer of the present embodiment, a cured product such as a film having excellent mechanical strength such as elongation can be obtained from the negative-type photosensitive polymer and the negative-type photosensitive resin composition containing the negative-type photosensitive polymer.

In addition, the negative-type photosensitive polymer of the present embodiment has an excellent solubility in a solvent and thus is not required to be in a precursor state when being varnished. Therefore, a varnish containing the negative-type photosensitive polymer can be prepared, which makes it possible to obtain a cured product such as a film from this varnish.

### <Method for Producing Negative-Type Photosensitive Polymer>

A method of the present embodiment for producing the negative-type photosensitive polymer, which has the structural unit (1-1a) represented by General Formula (1-1a) and/or the structural unit (1-1b) represented by General Formula (1-1b) and in which at least one of both terminals is the group t-1 represented by General Formula (t-1), includes a step of reacting an acid anhydride (a1) represented by General Formula (a1) below, a diamine (a2) represented by General Formula (a2) below and/or a diamine (a3) represented by General Formula (a3) below, and a maleic acid anhydride derivative (t1) represented by General Formula (t1) below.

According to the present embodiment, the polyimide (A) having excellent solubility in an organic solvent can be synthesized by a simple method.

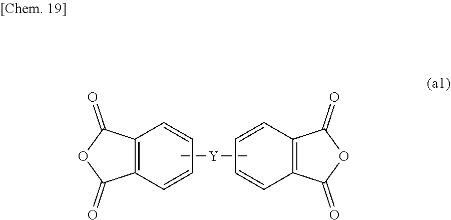

In General Formula (a1), Y is selected from the groups represented by General Formula (a1-1), (a1-2), (a1-3), or (a1-4) above.

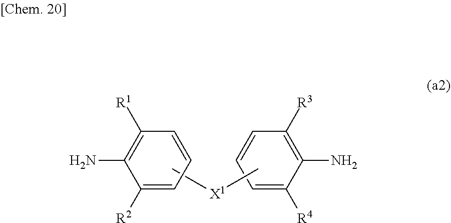

In General Formula (a2), R¹ to R⁴ and X¹ have the same definitions as those in General Formula (1a).

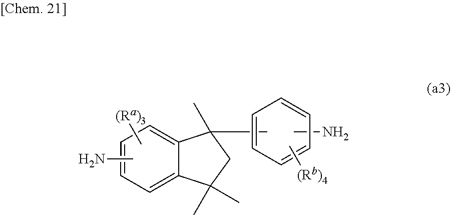

In General Formula (a3), R^{a} and R^{b} have the same definition as those in General Formula (1b).

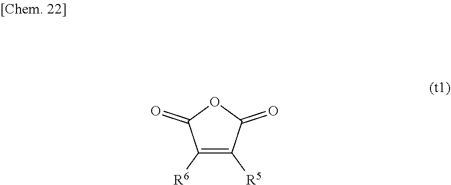

In General Formula (t1), R⁵ and R⁶ have the same definitions as those in General Formula (t) above.

The equivalent ratio of the diamine (a2) and/or the diamine (a3) in the reaction and the acid anhydride (a1) in the reaction is an important factor that determines the molecular weight of the obtained polyimide. In general, it is well known that there is a correlation between the molecular weight and the mechanical properties of a polymer, and the higher the molecular weight the better the mechanical properties. Accordingly, a molecular weight that is high to a certain degree is required to obtain a polyimide having a practically excellent strength. In the present invention, the equivalent ratio of the diamine (a2) and/or the diamine (a3) used and the acid anhydride (a1) used is not particularly limited, but the equivalent ratio of the acid anhydride (a1) to the diamine (a2) and/or the diamine (a3) is preferably within a range of 0.80 to 1.06. When the equivalent ratio is less than 0.80, the molecular weight is low, and brittleness is caused, resulting in a low mechanical strength. In addition, when the equivalent ratio is more than 1.06, this may not be preferable because the unreacted carboxylic acid is decarboxylated at the time of heating, which causes gas generation and foaming.

The molar amount of the maleic acid anhydride derivative (t1) can be set to three times the molar amount of the amino group not subjected to the reaction with the acid anhydride (a1).

Thus, the photosensitivity by photodimerization can be imparted to the polyimide, which makes it possible to obtain a cured product such as a film which is better in a low dielectric dissipation factor and which also has better mechanical properties.

This reaction can be carried out in an organic solvent by a known method.

Examples of the organic solvents include polar aprotic solvents such as γ-butyrolactone (GBL), N,N-dimethylformamide, N,N-dimethylacetamide, tetrahydrofuran, diethylene glycol dimethyl ether, diethylene glycol diethyl ether, cyclohexanone, and 1,4-dioxane, and one type or a combination of two or more types may be used. At this time, a non-polar solvent that is compatible with the above-mentioned polar aprotic solvent may be mixed and used. Examples of the non-polar solvents include aromatic hydrocarbons such as toluene, ethylbenzene, xylene, mesitylene, and solvent naphtha; and ether-based solvents such as cyclopentyl methyl ether. The proportion of the non-polar solvent in the mixed solvent can be arbitrarily set according to a stirring device ability and resin properties such as a solution viscosity as long as the proportion is not within a range in which the degree of solubility of the solvent decreases to the extent that a polyamide acid resin obtained by the reaction precipitates.

Regarding the reaction temperature, a reaction is caused for about 30 minutes to 2 hours at equal to or higher than 0° C. and equal to or lower than 100° C., preferably at equal to or higher than 20° C. and equal to or lower than 80° C., and thereafter a reaction is caused for about 1 hour to 5 hours at equal to or higher than 100° C. and equal to or lower than 250° C., preferably at equal to or higher than 120° C. and equal to or lower than 200° C.

The maleic acid anhydride derivative (t1) may be present in the imidization reaction of the acid anhydride (a1) with the diamine (a2) and/or the diamine (a3). Alternatively, during the reaction or after the completion of the reaction of the acid anhydride (a1) with the diamine (a2) and/or diamine (a3), the maleic acid anhydride derivative (t1) dissolved in the above-mentioned organic solvent can be added and reacted to block the terminal of the polyimide.

When the maleic acid anhydride derivative (t1) is separately added, the reaction is preferably carried out for about 1 to 5 hours after the addition at a temperature that is equal to or higher than 100° C. and equal to or lower than 250° C., and preferably equal to or higher than 120° C. and equal to or lower than 200° C.

Through the steps above, a reaction solution containing the negative-type photosensitive polymer (terminal-blocked polyimide) of the present embodiment can be obtained. Furthermore, as necessary, the reaction solution can be diluted with an organic solvent or the like to be used as a polymer solution (varnish for coating). As the organic solvent, those exemplified in the reaction step can be used, and the organic solvent may be the same organic solvent as in the reaction step or may be a different organic solvent.

In addition, a resultant product, which is obtained by putting this reaction solution into a poor solvent to cause redeposition precipitation of the negative-type photosensitive polymer, removing unreacted monomers, and drying to solidify, can be dissolved again in an organic solvent to be used as a purified product. Particularly in usage in which impurities and foreign materials are problematic, it is preferable to carry out dissolution in an organic solvent again to obtain a filtration-purified varnish.

The concentration of the negative-type photosensitive polymer in the polymer solution (100% by weight) is not particularly limited, but is about 10% to 30% by weight.

Table A below shows preferable blending examples of the negative-type photosensitive polymer of the present embodiment.

TABLE A

| | | | | Terminal- |
|---|---|---|---|---|
| | Diamine | Diamine | Acid | blocked |
| | compound 1 | compound 2 | anhydride | compound |
| Blending | MED-J | Not used | TMPBP-TME | DMMI |
| Example 1 | | | | |
| Blending | MED-J | Not used | HQDA | DMMI |
| Example 2 | | | | |
| Blending | MED-J | TMDA | TMPBP-TME | DMMI |
| Example 3 | | | | |
| Blending | MED-J | BTFL | TMPBP-TME | DMMI |
| Example 4 | | | | |
| Blending | MED-J | TMDA | HQDA | DMMI |
| Example 5 | | | | |
| Blending | MED-J | BTFL | HQDA | DMMI |
| Example 6 | | | | |
| Blending | Not used | TMDA | TMPBP-TME | DMMI |
| Example 7 | | | | |
| Blending | Not used | BTFL | TMPBP-TME | DMMI |
| Example 8 | | | | |
| Blending | Not used | TMDA | HQDA | DMMI |
| Example 9 | | | | |
| Blending | Not used | BTFL | HQDA | DMMI |
| Example 10 | | | | |

MED-J: 4,4-diamino-3,3-diethyl-5,5-dimethyldiphenylmethane
TMPBP-TME: 4-[4-(1,3-dioxoisobenzofuran-5-ylcarbonyloxy)-2,3,5-trimethylphenyl]-2,3,6-trimethylphenyl 1,3-dioxoisobenzofuran-5-carboxylate
HQDA: 1,4-bis(3,4-dicarboxyphenoxy)benzene dianhydride
TMDA: mixture of 1-(4-aminophenyl)-1,3,3-trimethylphenylindan-6-amine and 1-(4-aminophenyl)-1,3,3-trimethylphenylindan-5-amine
BTFL: 9,9-bis(3-methyl-4-aminophenyl)fluorene
DMMI: 2,3-dimethylmaleic anhydride

### [Characteristics of Negative-Type Photosensitive Polymer]

The negative-type photosensitive polymer of the present embodiment has excellent solvent solubility, and equal to or more than 5% by mass thereof can be dissolved in a solvent selected from N-methyl-2-pyrrolidone, N-ethyl-2-pyrrolidone, γ-butyrolactone (GBL), and cyclopentanone, and particularly equal to or more than 5% by mass thereof can be dissolved in cyclopentanone.

The negative-type photosensitive polymer of the present embodiment is solvent-soluble, and thus can be suitably used as a polymer solution (varnish).

The negative-type photosensitive polymer of the present embodiment has excellent hydrolysis resistance, and the reduction rate of the weight-average molecular weight thereof measured under the following conditions is equal to or less than 15%, preferably equal to or less than 12%, further preferably equal to or less than 11%, and particularly preferably equal to or less than 10%.

### (Condition)

When 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression.

Expression: [(weight-average molecular weight before test−weight-average molecular weight after test)/weight-average molecular weight before test]×100

When the reduction rate of the weight-average molecular weight of the negative-type photosensitive polymer of the present embodiment is within the above-mentioned range, it is possible to obtain a cured product such as a film in which a reduction in mechanical strength such as elongation is minimized.

The negative-type photosensitive polymer of the present embodiment has excellent hydrolysis resistance, and the reduction rate of the weight-average molecular weight thereof measured under the following conditions is equal to or less than 50%, preferably equal to or less than 40%, and further preferably equal to or less than 30%.

### (Condition)

When 10 parts by mass of triethylamine, 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression.

$$Expression : [ ( weight - average molecular weight before test - weight - average molecular weight after test ) / weight - average molecular weight before test ] \times 100$$

The reduction rate of the weight-average molecular weight of the negative-type photosensitive polymer of the present embodiment can be set within the above-mentioned range even under the above-mentioned conditions where it is more susceptible to hydrolysis, and it is possible to obtain a cured product such as a film in which a reduction in mechanical strength such as elongation is further minimized.

### <Negative-Type Photosensitive Resin Composition>

The negative-type photosensitive resin composition of the present embodiment contains (A) the above-mentioned negative-type photosensitive polymer, (B) a crosslinking agent, and (C) a photosensitizer.

### [Crosslinking Agent (B)]

Examples of the crosslinking agent (B) (excluding the above-mentioned polyimide (A)) having a substituted or unsubstituted maleimide group include 4,4′-diphenylmethane bis(dimethyl)maleimide, polyphenylmethane (dimethyl)maleimide, m-phenylene bis(dimethyl)maleimide, p-phenylene bis(dimethyl)maleimide, bisphenol A diphenyl ether bis(dimethyl)maleimide, 3,3′-dimethyl-5,5′-diethyl-4,4′-diphenylmethane bis(dimethyl)maleimide, 4-methyl-1,3-phenylene bis(dimethyl)maleimide, 1,6′-bis(dimethyl)maleimide-(2,2,4-trimethyl)hexane, 1,2-bis((dimethyl)maleimide)ethane, 1,4-bis((dimethyl)maleimide)butane, 1,6-bis((dimethyl)maleimide)hexane, 1,12-bis((dimethyl)maleimide)dodecane, 1-(dimethyl)maleimide-3-(dimethyl)maleimidemethyl-3,5,5-trimethylcyclohexane, 1,1′-(cyclohexane-1,3-diylbis(methylene))bis((3,4-dimethyl)-1H-pyrrole-2,5-dione), 1,1′-(4,4′methylenebis(cyclohexane-4,1-diyl))bis((3,4-dimethyl)-1H-pyrrole-2,5-dione), 1,1′-(3,3′-(piperazine-1,4-diyl)bis(propane-3,1-diyl))bis(1H-pyrrole-2,5-dione), 2,2′-(ethylenedioxy)bis(ethyl(dimethyl)maleimide), and polynorbornene having a substituted or unsubstituted maleimide group, among which the polynorbornene is preferable.

The above-mentioned polynorbornene preferably has a structural unit (b) represented by General Formula (b) below.

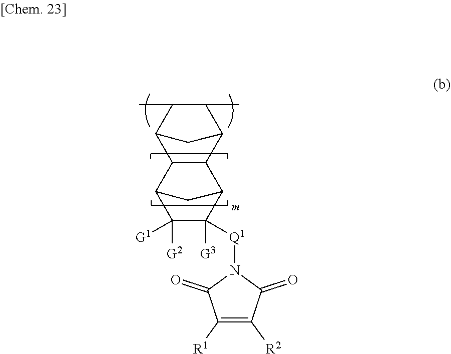

In General Formula (b), R¹ and R² each independently represent a hydrogen atom or an alkyl group having 1 to 3 carbon atoms. It is preferable that at least one of R¹ and R² be an alkyl group having 1 to 3 carbon atoms, and it is more preferable that both thereof be an alkyl group having 1 to 3 carbon atoms. From the viewpoint of the effects of the present invention, the alkyl group having 1 to 3 carbon atoms is preferably an alkyl group having 1 or 2 carbon atoms, and more preferably an alkyl group having 1 carbon atom.

Q¹ represents a single bond or a divalent organic group.

As the above-mentioned divalent organic group as Q¹, a known organic group can be used within a range in which the effects of the present invention are exhibited. Examples thereof include an alkylene group having 1 to 8 carbon atoms or a (poly)alkylene glycol chain. The alkylene group having 1 to 8 carbon atoms is preferably an alkylene group having 2 to 6 carbon atoms.

Examples of the alkylene groups having 1 to 8 carbon atoms include a methylene group, an ethylene group, a propylene group, a butylene group, a pentylene group, a hexylene group, a heptylene group, and an octylene group.

An alkylene oxide constituting the (poly)alkylene glycol chain is not particularly limited, but the (poly)alkylene glycol chain is composed of preferably an alkylene oxide having 1 to 18 carbon atoms, and more preferably an alkylene oxide having 2 to 8 carbon atoms. Examples thereof include ethylene oxide, propylene oxide, butylene oxide, isobutylene oxide, 1-butene oxide, 2-butene oxide, trimethylethylene oxide, tetramethylene oxide, tetramethylethylene oxide, butadiene monooxide, and octylene oxide.

G¹, G², and G³ each independently represent a hydrogen atom or a substituted or unsubstituted hydrocarbon group having 1 to 30 carbon atoms.

Examples of the hydrocarbon groups having 1 to 30 carbon atoms include an alkyl group, an alkenyl group, an alkynyl group, an alkylidene group, an aryl group, an aralkyl group, an alkaryl group, and cycloalkyl.

Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group.

Examples of the alkenyl group include an allyl group, a pentenyl group, and a vinyl group. Examples of the alkynyl group include an ethynyl group.

Examples of the alkylidene group include a methylidene group and an ethylidene group.

Examples of the aryl group include a phenyl group, a naphthyl group, and an anthracenyl group. Examples of the aralkyl group include a benzyl group and a phenethyl group.

Examples of the alkaryl group include a tolyl group and a xylyl group. Examples of the cycloalkyl group include an adamantyl group, a cyclopentyl group, a cyclohexyl group, and a cyclooctyl group.

The hydrocarbon group having 1 to 30 carbon atoms may have at least one atom selected from O, N, S, P, and Si in its structure.

In the present embodiment, the above-mentioned hydrocarbon group having 1 to 30 carbon atoms is preferably a hydrocarbon group having 1 to 15 carbon atoms, and more preferably a hydrocarbon group having 1 to 10 carbon atoms. In addition, the hydrocarbon group having 1 to 30 carbon atoms is preferably an alkyl group having 1 to 30 carbon atoms, more preferably an alkyl group having 1 to 15 carbon atoms, and further preferably an alkyl group having 1 to 10 carbon atoms.

Examples of substituents of the substituted hydrocarbon group having 1 to 30 carbon atoms include a hydroxyl group, an amino group, a cyano group, an ester group, an ether group, an amide group, and a sulfonamide group, and the hydrocarbon group may be substituted with at least one group.

In the present embodiment, it is preferable that any one of G¹, G², and G³ be a substituted or unsubstituted hydrocarbon group having 1 to 30 carbon atoms, and that the rest be hydrogen atoms; and it is more preferable that all of them be hydrogen atoms.

m is 0, 1, or 2, and is preferably 0 or 1, and more preferably 0.

The crosslinking agent (B) of the present embodiment has the structure represented by General Formula (b), and thus is excellent in a low dielectric dissipation factor. Furthermore, since the crosslinking agent (B) has a predetermined maleimide group at a side chain thereof and can be photodimerized without causing a radical reaction, the crosslinking agents (B) can be photopolymerized with each other, and the crosslinking agent (B) and the polyimide (A) can be photopolymerized, which makes mechanical strength excellent.

The crosslinking agent (B) of the present embodiment can be synthesized as follows.

First, a compound (b′) represented by General Formula (b′) below is addition-polymerized, and is addition-polymerized with another norbornene-based compound as necessary to obtain a polymer. The addition polymerization is carried out by coordination polymerization, for example.

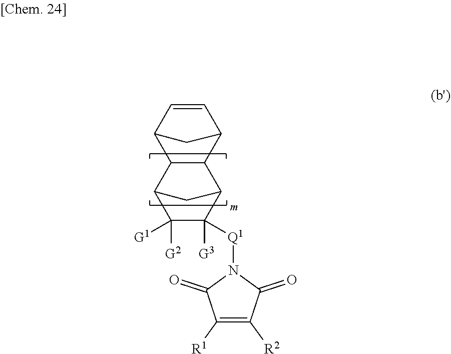

In General Formula (b′), R¹, R², Q¹, G¹, G², G³, and m have the same definitions as those in General Formula (b).

Examples of the other norbornene-based compounds include norbornenes having an alkyl group such as 5-methylnorbornene, 5-ethylnorbornene, 5-butylnorbornene, 5-hexylnorbornene, 5-decylnorbornene, 5-cyclohexylnorbornene, and 5-cyclopentylnorbornene; norbornenes having an alkenyl group such as 5-ethylidenenorbornene, 5-vinylnorbornene, 5-propenylnorbornene, 5-cyclohexenylnorbornene, and 5-cyclopentenylnorbornene; norbornenes having an aromatic ring such as 5-phenylnorbornene, 5-phenylmethylnorbornene, 5-phenylethylnorbornene, and 5-phenylpropylnorbornene.

In the present embodiment, solution polymerization can be performed by dissolving the above-mentioned compound and an organometallic catalyst in a solvent, and thereafter heating for a predetermined time. At this time, the heating temperature can be set to 30° C. to 200° C., preferably 40° C. to 150° C., and more preferably 50° C. to 120° C., for example. In the present embodiment, the yield of the crosslinking agent (B) can be improved by making the heating temperature higher than that in the related art.

In addition, the heating time can be 0.5 hours to 72 hours, for example. It is more preferable that the solution polymerization be performed after removing dissolved oxygen in the solvent by nitrogen bubbling.

In addition, a molecular weight control agent and a chain transfer agent can be used, as necessary. Examples of the chain transfer agents include alkylsilane compounds such as trimethylsilane, triethylsilane, and tributylsilane. For these chain transfer agents, one type may be used alone, or two or more types may be used in combination.

As a solvent used in the above-mentioned polymerization reaction, it is possible to use one or two or more of methyl ethyl ketone (MEK), propylene glycol monomethyl ether, diethyl ether, cyclopentyl methyl ether, tetrahydrofuran (THF), 4-methyltetrahydropyran, toluene, cyclohexane, methylcyclohexane, esters such as ethyl acetate and butyl acetate, and alcohols such as methyl alcohol, ethyl alcohol, and isopropyl alcohol.

The above-mentioned organometallic catalyst is not particularly selected as long as the addition polymerization proceeds, but for example, a phosphine-based or diimine-based ligand may be coordinated in a palladium complex and a nickel complex to use a counter anion or the like. Among these, one type or two or more types can be used.

Examples of the above-mentioned palladium complex include (acetato-κ0) (acetonitrile)bis[tris(1-methylethyl)phosphine]palladium(I) tetrakis(2,3,4,5,6-pentafluorophenyl)borate; allyl palladium complexes such as n-allylpalladium chloride dimer;
organic carboxylic acid salts of palladium such as acetic acid salts, propionic acid salts, maleic acid salts, and naphthoic acid salts of palladium;
organic carboxylic acid complexes of palladium such as a triphenylphosphine complex of palladium acetate, a tri(m-tolyl)phosphine complex of palladium acetate, and a tricyclohexylphosphine complex of palladium acetate;
organic sulfonic acid salts of palladium such as dibutyl phosphorous acid salts and p-toluenesulfonic acid salts of palladium;
β-diketone compounds of palladium such as bis(acetylacetonate)palladium, bis(hexafluoroacetylacetonate)palladium, bis(ethylacetoacetate)palladium, and bis(phenylacetoacetate)palladium; and
halide complexes of palladium such as dichlorobis(triphenylphosphine)palladium, bis[tri(m-tolylphosphine)]palladium, dibromobis[tri(m-tolylphosphine)]palladium, and an acetonyltriphenylphosphonium complex.

Examples of the above-mentioned phosphine ligand include triphenylphosphine, dicyclohexylphenylphosphine, cyclohexyldiphenylphosphine, and tricyclohexylphosphine.

Examples of the above-mentioned counter anion include triphenylcarbenium tetrakis(pentafluorophenyl)borate, triphenylcarbenium tetrakis[3,5-bis(trifluoromethyl)phenyl]borate, triphenylcarbenium tetrakis(2,4,6-trifluorophenyl)borate, triphenylcarbenium tetraphenylborate, tributylammonium tetrakis(pentafluorophenyl)borate, N,N-dimethylanilinium tetrakis(pentafluorophenyl)borate, N,N-diethylanilinium tetrakis(pentafluorophenyl)borate, N,N-diphenylanilinium tetrakis(pentafluorophenyl)borate, and lithium tetrakis(pentafluorophenyl)borate.

The amount of the organometallic catalyst with respect to the norbornene-based monomer can be set to 300 ppm to 5,000 ppm, preferably 1,000 ppm to 3,500 ppm, and more preferably 1,500 ppm to 2,500 ppm. Thus, the yield of the crosslinking agent (B) can be improved.

A reaction liquid containing the obtained crosslinking agent (B) is added to, for example, an alcohol such as hexane and methanol to precipitate the crosslinking agent (B). Subsequently, the crosslinking agent (B) is collected by filtration, cleaned with, for example, an alcohol such as hexane and methanol, and thereafter dried.

In the present embodiment, the crosslinking agent (B) can be synthesized in as above, for example.

According to the production method of the present embodiment, the crosslinking agent (B) can be obtained with a high yield of equal to or more than 70%.

The rate of conversion with dialkyl maleic acid anhydride is preferably equal to or more than 70%. The rate of conversion is more preferably 80%, and further preferably equal to or more than 90%. Within this range, the polyimide component eluted by development can be reduced.

The crosslinking agent (B) of the present embodiment can have another structural unit other than the structural unit (b) within a range in which the effects of the present invention are exhibited. Examples of the other structural units include structural units derived from the other norbornene-based compounds mentioned above.

The weight-average molecular weight of the crosslinking agent (B) of the present embodiment is 3,000 to 300,000, and preferably 5,000 to 200,000.

In the present embodiment, from the viewpoint of the effects of the present invention, the ratio (A:B) of the negative-type photosensitive polymer (A) and the crosslinking agent (B) is 5:95 to 95:5, preferably 10:90 to 90:10, and more preferably 20:80 to 80:20.

### [Photosensitizer (C)]

The negative-type photosensitive resin composition of the present embodiment can further contain the photosensitizer (C).

Examples of the photosensitizer (C) include a benzophenone-based photopolymerization initiator, a thioxanthone-based photopolymerization initiator, a benzyl-based photopolymerization initiator, and a Michler's ketone-based photopolymerization initiator. Among these, a benzophenone-based photopolymerization initiator and a thioxanthone-based photopolymerization initiator are preferable.

Examples of the benzophenone-based photopolymerization initiators include benzophenone, 4-chlorobenzophenone, 4,4′-dimethoxybenzophenone, 4,4′-diaminobenzophenone, 4-phenylbenzophenone, isophthalphenone, and 4-benzoyl-4′-methyldiphenyl sulfide. These benzophenones and derivatives thereof can improve a curing speed with a tertiary amine as a hydrogen donor.

Examples of commercially available products of the benzophenone-based photopolymerization initiators include SPEEDCURE MBP (4-methylbenzophenone), SPEEDCURE MBB (methyl-2-benzoylbenzoate), SPPEDCURE BMS (4-benzoyl-4′methyldiphenyl sulfide), SPPEDCURE PBZ (4-phenylbenzophenone), and SPPEDCURE EMK (4,4′-bis(diethylamino)benzophenone) (all trade names, manufactured by DKSH Japan K.K.).

Examples of the thioxanthone-based photopolymerization initiators include thioxanthone, diethylthioxanthone, isopropylthioxanthone, and chlorothioxanthone. As diethylthioxanthone, 2,4-diethylthioxanthone is preferable. As isopropylthioxanthone, 2-isopropylthioxanthone is preferable. As chlorothioxanthone, 2 chlorothioxanthone is preferable. Among those, the thioxanthone-based photopolymerization initiators including diethylthioxanthone are more preferable.

Examples of commercially available products of the thioxanthone-based photopolymerization initiators include Speedcure DETX (2,4-diethylthioxanthone), Speedcure ITX (2-isopropylthioxanthone), Speedcure CTX (2-chlorothioxanthone), and SPEEDCURE CPTX (1-chloro-4-propylthioxanthone) (all trade names, manufactured by DKSH Japan K.K.), KAYACURE DETX (2,4-diethylthioxanthone) (trade name, manufactured by Nippon Kayaku Co., Ltd.), and DAIDO UV-CURE DETX (manufactured by Daido Chemical Corporation).

The addition amount of the photosensitizer (C) is not particularly limited, but is preferably about 0.05% to 15% by mass, is more preferably about 0.1% to 12.5% by mass, and is further preferably about 0.2% to 10% by mass of the total solid content of the negative-type photosensitive resin composition. By setting the addition amount of the photosensitizer (C) within the above-mentioned range, the patterning properties of a photosensitive resin layer containing the negative-type photosensitive resin composition can be improved, and also, the long-term storability of the negative-type photosensitive resin composition can be improved.

### [Silane Coupling Agent (D)]

The negative-type photosensitive resin composition of the present embodiment can further contain a silane coupling agent (D).

Thus, the adhesiveness of a resin film and a pattern formed from the negative-type photosensitive resin composition to a substrate can be enhanced.

The silane coupling agent (D) that can be used is not particularly limited. For example, it is possible to use a silane coupling agent such as aminosilane, epoxysilane, acrylsilane, mercaptosilane, vinylsilane, ureidosilane, acid anhydride-functional silane, and sulfidesilane. For the silane coupling agent (D), one type may be used alone, and two or more types may be used in combination. Among these, epoxysilane (that is, a compound containing, in one molecule, both an epoxy moiety and a group that generates a silanol group by hydrolysis) or acid anhydride-functional silane (that is, a compound containing, in one molecule, both an acid anhydride group and a group that generates a silanol group by hydrolysis) is preferable. The group on the side opposite to the silane of the silane coupling agent bonds to a polymer A or a polymer B to become compatible with the polymer, which makes it possible to further enhance the adhesiveness of a resin film and a pattern formed from the negative-type photosensitive resin composition to a substrate.

Examples of aminosilanes include bis(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-β(aminoethyl) γ-aminopropyltrimethoxysilane, N-β(aminoethyl) γ-aminopropyltriethoxysilane, N-β(aminoethyl) γ-aminopropylmethyldimethoxysilane, N-β(aminoethyl) γ-aminopropylmethyldiethoxysilane, and N-phenyl-γ-aminopropyltrimethoxysilane.

Examples of epoxysilanes include γ-glycidoxypropyltrimethoxysilane, γ-glycidoxypropylmethyldiethoxysilane, β-(3,4-epoxycyclohexyl)ethyltrimethoxysilane, and γ-glycidylpropyltrimethoxysilane.

Examples of acrylsilanes include γ-(methacryloxypropyl)trimethoxysilane, γ-(methacryloxypropyl)methyldimethoxysilane, and γ-(methacryloxypropyl)methyldiethoxysilane.

Examples of mercaptosilanes include 3-mercaptopropyltrimethoxysilane.

Examples of vinylsilanes include vinyltris(R-methoxyethoxy)silane, vinyltriethoxysilane, and vinyltrimethoxysilane.

Examples of ureidosilanes include 3-ureidopropyltriethoxysilane.

Examples of acid anhydride-functional silanes include 3-trimethoxysilylpropylsuccinic anhydride.

Examples of sulfidesilanes include bis(3-(triethoxysilyl)propyl)disulfide and bis(3-(triethoxysilyl)propyl)tetrasulfide.

When using the silane coupling agent (D), only one type may be used, or two or more types may be used in combination.

The content of the silane coupling agent (D) is generally 0.01 to 10 parts by mass, and preferably 0.05 to 5 parts by mass when the total solid content of the negative-type photosensitive resin composition is set to 100 parts by mass. Within this range, it is thought that a sufficient level of “adhesiveness” which is the effect of the silane coupling agent (D) can be obtained while maintaining a balance with the other performances.

### (Solvent)

The negative-type photosensitive resin composition according to the present embodiment can contain, as a solvent, a urea compound or an amide compound having an acyclic structure. The solvent preferably includes a urea compound, for example. Thus, the adhesiveness of a cured product of the negative-type photosensitive resin composition to a metal such as Al and Cu can be further enhanced.

In the present specification, the urea compound refers to a compound having a urea bond. In addition, the amide compound refers to a compound having an amide bond, that is, an amide. Specific examples of amides include a primary amide, a secondary amide, and a tertiary amide.

In addition, in the present embodiment, the acyclic structure means that the structure of a compound does not include a cyclic structure such as a carbocyclic ring, an inorganic ring, and a heterocyclic ring. Examples of structures of a compound not having a cyclic structure include a straight-chain structure and a branched-chain structure.

As the urea compound and the amide compound having an acyclic structure, those having a large number of nitrogen atoms in the molecular structure are preferable. Specifically, the number of nitrogen atoms in the molecular structure is preferably equal to or more than 2. Thus, the number of lone electron pairs can be increased. Accordingly, the adhesiveness to a metal such as Al and Cu can be enhanced.

Specific examples of structures of the urea compound include a cyclic structure and an acyclic structure. Among the above-mentioned specific examples, the acyclic structure is preferable as the structure of the urea compound. Thus, the adhesiveness of a cured product of the negative-type photosensitive resin composition to a metal such as Al and Cu can be enhanced. A reason thereof is presumed to be as follows. It is presumed that a urea compound having an acyclic structure forms a coordinate bond more easily than a urea compound having a cyclic structure. This is thought to be because in the urea compound having an acyclic structure, the molecular motion is less constrained, and also, a degree of freedom in deformation of the molecular structure is higher, as compared to the urea compound having a cyclic structure. Accordingly, when the urea compound having an acyclic structure is used, a strong coordinate bond can be formed, which makes it possible to enhance the adhesiveness.

Specific examples of urea compounds include tetramethylurea (TMU), 1,3-dimethyl-2-imidazolidinone, tetrabutylurea, N,N′-dimethylpropyleneurea, 1,3-dimethoxy-1,3-dimethylurea, N,N′-diisopropyl-O-methylisourea, O,N,N′-triisopropylisourea, O-tert-butyl-N,N′-diisopropylisourea, O-ethyl-N,N′-diisopropylisourea, and O-benzyl-N,N′-diisopropylisourea. As the urea compound, one of the above-mentioned specific examples can be used, or two or more thereof can be used in combination. As the urea compound, among the above-mentioned specific examples, it is preferable to use one or two or more selected from the group consisting of tetramethylurea (TMU), tetrabutylurea, 1,3-dimethoxy-1,3-dimethylurea, N,N′-diisopropyl-O-methylisourea, O,N,N′-triisopropylisourea, O-tert-butyl-N,N′-diisopropylisourea, O-ethyl-N,N′-diisopropylisourea, and O-benzyl-N,N′-diisopropylisourea, and it is more preferable use tetramethylurea (TMU). Thus, a strong coordinate bond can be formed, which makes it possible to enhance the adhesiveness.

Specific examples of amide compounds having an acyclic structure include 3-methoxy-N,N-dimethylpropanamide, N,N-dimethylformamide, N,N-dimethylpropionamide, N,N-dimethylacetamide, N,N-diethylacetamide, 3-butoxy-N,N-dimethylpropanamide, and N,N-dibutylformamide.

The negative-type photosensitive resin composition according to the present embodiment may contain, as a solvent, a solvent not having a nitrogen atom in addition to the urea compound and the amide compound having an acyclic structure.

Specific examples of the solvents not having a nitrogen atom include ether-based solvents, ester-based solvents, alcohol-based solvents, ketone-based solvents, lactone-based solvents, carbonate-based solvents, sulfone-based solvents, ester-based solvents, and aromatic hydrocarbon-based solvents. As the solvent not having a nitrogen atom, one of the above-mentioned specific examples can be used, or two or more thereof can be used in combination.

Specific examples of the above-mentioned ether-based solvents include propylene glycol monomethyl ether (PGME), propylene glycol monoethyl ether, ethylene glycol monoethyl ether, diethylene glycol dimethyl ether, diethylene glycol monoethyl ether, diethylene glycol, ethylene glycol diethyl ether, diethylene glycol diethyl ether, diethylene glycol dibutyl ether, dipropylene glycol monomethyl ether, and 1,3-butylene glycol-3-monomethyl ether.

Specific examples of the above-mentioned ester-based solvents include propylene glycol monomethyl ether acetate (PGMEA), methyl lactate, ethyl lactate, butyl lactate, and methyl-1,3-butylene glycol acetate.

Specific examples of the above-mentioned alcohol-based solvents include tetrahydrofurfuryl alcohol, benzyl alcohol, 2-ethylhexanol, butanediol, and isopropyl alcohol.

Specific examples of the above-mentioned ketone-based solvents include cyclopentanone, cyclohexanone, diacetone alcohol, and 2-heptanone.

Specific examples of the above-mentioned lactone-based solvents include γ-butyrolactone (GBL) and γ-valerolactone.

Specific examples of the above-mentioned carbonate-based solvents include ethylene carbonate and propylene carbonate.

Specific examples of the sulfone-based solvents include dimethyl sulfoxide (DMSO) and sulfolane.

Specific examples of the above-mentioned ester-based solvents include methyl pyruvate, ethyl pyruvate, and methyl-3-methoxypropionate.

Specific examples of the aromatic hydrocarbon-based solvents include mesitylene, toluene, and xylene.

When the solvent is set to 100 parts by mass, the lower limit value of the content of the urea compound and the amide compound having an acyclic structure in the solvent is preferably equal to or more than 10 parts by mass, more preferably equal to or more than 20 parts by mass, further preferably equal to or more than 30 parts by mass, still further preferably equal to or more than 50 parts by mass, and particularly preferably equal to or more than 70 parts by mass, for example. Thus, the adhesiveness of a cured product of the negative-type photosensitive resin composition to a metal such as Al and Cu can be further enhanced.

In addition, when the solvent is set to 100 parts by mass, the lower limit value of the content of the urea compound and the amide compound having an acyclic structure in the solvent can be equal to or less than 100 parts by mass, for example. The content of the urea compound and the amide compound having an acyclic structure is preferably high in the solvent from the viewpoint of enhancing adhesiveness.

### (Surfactant)

The negative-type photosensitive resin composition according to the present embodiment may further contain a surfactant.

A surfactant is not particularly limited, and specific examples thereof include polyoxyethylene alkyl ethers such as polyoxyethylene lauryl ether, polyoxyethylene stearyl ether, and polyoxyethylene oleyl ether; polyoxyethylene aryl ethers such as polyoxyethylene octylphenyl ether and polyoxyethylene nonylphenyl ether; nonionic surfactants such as polyoxyethylene dialkyl esters such as polyoxyethylene dilaurate and polyoxyethylene distearate; F-TOP EF301, F-TOP EF303, and F-TOP EF352 (manufactured by Shin Akita Kasei Co., Ltd.); MEGAFACE F171, MEGAFACE F172, MEGAFACE F173, MEGAFACE F177, MEGAFACE F444, MEGAFACE F470, MEGAFACE F471, MEGAFACE F475, MEGAFACE F482, and MEGAFACE F477 (manufactured by DIC Corporation); Fluorad FC-430, Fluorad FC-431, Novec FC4430, and Novec FC4432 (manufactured by 3M Japan Ltd.); fluorine-based surfactants commercially available under names such as SURFLON S-381, SURFLON S-382, SURFLON S-383, SURFLON S-393, SURFLON SC-101, SURFLON SC-102, SURFLON SC-103, SURFLON SC-104, SURFLON SC-105, and SURFLON SC-106 (manufactured by AGC SEIMI CHEMICAL CO., LTD.); an organosiloxane copolymer KP341 (manufactured by Shin-Etsu Chemical Co., Ltd.); and a (meth)acrylic acid copolymer Polyflow Nos. 57 and 95 (manufactured by KYOEISHA CHEMICAL Co., LTD.).

Among these, a fluorine-based surfactant having a perfluoroalkyl group is preferably used. Among the above-mentioned specific examples, as the fluorine-based surfactant having a perfluoroalkyl group, it is preferable to use one or two or more selected from MEGAFACE F171, MEGAFACE F173, MEGAFACE F444, MEGAFACE F470, MEGAFACE F471, MEGAFACE F475, MEGAFACE F482, and MEGAFACE F477 (manufactured by DIC Corporation); SURFLON S-381, SURFLON S-383, and SURFLON S-393 (manufactured by AGC SEIMI CHEMICAL CO., LTD.); and Novec FC4430 and Novec FC4432 (manufactured by 3M Japan Ltd.).

In addition, as the surfactant, a silicone-based surfactant (such as polyether-modified dimethylsiloxane) can also be preferably used. Specific examples of the silicone-based surfactants include SH series, SD series, and ST series of Dow Corning Toray Co., Ltd.; BYK series of BYK-Chemie Japan K.K.; KP series of Shin-Etsu Chemical Co., Ltd.; DISFOAM (registered trademark) series of NOF CORPORATION; and TSF series of Toshiba Silicones Co., Ltd.

The upper limit value of the content of the surfactant in the negative-type photosensitive resin composition is preferably equal to or less than 1% by mass (10,000 ppm), more preferably equal to or less than 0.5% by mass (5,000 ppm), and further preferably equal to or less than 0.3% by mass (3,000 ppm) with respect to the entirety (including the solvent) of the negative-type photosensitive resin composition.

In addition, the lower limit value of the content of the surfactant in the negative-type photosensitive resin composition is not particularly limited, but is equal to or more than 0.001% by mass (10 ppm), for example, with respect to the entirety (including the solvent) of the negative-type photosensitive resin composition from the viewpoint of sufficiently obtaining the effect of the surfactant.

By appropriately adjusting the amount of the surfactant, the applicability, the uniformity of a coating film, and the like can be enhanced while maintaining the other performances.

### (Antioxidant)

The negative-type photosensitive resin composition according to the present embodiment may further contain an antioxidant. As the antioxidant, it is possible to use one or more selected from a phenol-based antioxidant, a phosphorus-based antioxidant, and a thioether-based antioxidant. The antioxidant can inhibit the oxidation of a resin film formed from the negative-type photosensitive resin composition.

Examples of the phenol-based antioxidants include pentaerythrityl-tetrakis[3-(3,5-di-t-butyl-4-hydroxyphenyl)propionate], 3,9-bis{2-[3-(3-t-butyl-4-hydroxy-5-methylphenyl)propionyloxy]-1,1-dimethylethyl}2,4,8,10-tetraoxaspiro[5,5]undecane, octadecyl-3-(3,5-di-t-butyl-4-hydroxyphenyl)propionate, 1,6-hexanediol-bis[3-(3,5-di-t-butyl-4-hydroxyphenyl)propionate], 1,3,5-trimethyl-2,4,6-tris(3,5-di-t-butyl-4-hydroxybenzyl)benzene, 2,6-di-t-butyl-4-methylphenol, 2,6-di-t-butyl-4-ethylphenol, 2,6-diphenyl-4-octadecyloxyphenol, stearyl (3,5-di-t-butyl-4-hydroxyphenyl)propionate, distearyl (3,5-di-t-butyl-4-hydroxybenzyl)phosphonate, thiodiethylene glycol bis[(3,5-di-t-butyl-4-hydroxyphenyl)propionate], 4,4′-thiobis (6-t-butyl-m-cresol), 2-octylthio-4,6-di(3,5-di-t-butyl-4-hydroxyphenoxy)-s-triazine, 2,2′-methylenebis(4-methyl-6-t-butyl-6-butylphenol), 2,-2′-methylenebis(4-ethyl-6-t-butylphenol), bis[3,3-bis(4-hydroxy-3-t-butylphenyl)butyric acid] glycol ester, 4,4′-butylidenebis(6-t-butyl-m-cresol), 2,2′-ethylidenebis(4,6-di-t-butylphenol), 2,2′-ethylidenebis(4-s-butyl-6-t-butylphenol), 1,1,3-tris(2-methyl-4-hydroxy-5-t-butylphenyl)butane, bis[2-t-butyl-4-methyl-6-(2-hydroxy-3-t-butyl-5-methylbenzyl)phenyl] terephthalate, 1,3,5-tris(2,6-dimethyl-3-hydroxy-4-t-butylbenzyl)isocyanurate, 1,3,5-tris(3,5-di-t-butyl-4-hydroxybenzyl)-2,4,6-trimethylbenzene, 1,3,5-tris[(3,5-di-t-butyl-4-hydroxyphenyl)propionyloxyethyl]isocyanurate, tetrakis[methylene-3-(3,5-di-t-butyl-4-hydroxyphenyl)propionate]methane, 2-t-butyl-4-methyl-6-(2-acryloyloxy-3-t-butyl-5-methylbenzyl)phenol, 3,9-bis(1,1-dimethyl-2-hydroxyethyl)-2,4-8,10-tetraoxaspiro[5,5]undecane-bis[B-(3-t-butyl-4-hydroxy-5-methylphenyl)propionate], triethylene glycol bis[B-(3-t-butyl-4-hydroxy-5-methylphenyl)propionate], 1,1′-bis(4-hydroxyphenyl)cyclohexane, 2,2′-methylenebis(4-methyl-6-t-butylphenol), 2,2′-methylenebis(4-ethyl-6-t-butylphenol), 2,2′-methylenebis(6-(1-methylcyclohexyl)-4-methylphenol), 4,4′-butylidenebis(3-methyl-6-t-butylphenol), 3,9-bis(2-(3-t-butyl-4-hydroxy-5-methylphenylpropionyloxy)1,1-dimethylethyl)-2,4,8,10-tetraoxaspiro(5,5)undecane, 4,4′-thiobis(3-methyl-6-t-butylphenol), 4,4′-bis(3,5-di-t-butyl-4-hydroxybenzyl)sulfide, 4,4′-thiobis(6-t-butyl-2-methylphenol), 2,5-di-t-butylhydroquinone, 2,5-di-t-amylhydroquinone, 2-t-butyl-6-(3-t-butyl-2-hydroxy-5-methylbenzyl)-4-methylphenylacrylate, 2,4-dimethyl-6-(1-methylcyclohexyl, styrenated phenol, and 2,4-bis((octylthio)methyl)-5-methylphenol.

Examples of the phosphorus-based antioxidants include bis(2,6-di-t-butyl-4-methylphenyl)pentaerythritol diphosphite, tris(2,4-di-t-butylphenyl phosphite), tetrakis(2,4-di-t-butyl-5-methylphenyl)-4,4′-biphenylene diphosphonite, 3,5-di-t-butyl-4-hydroxybenzylphosphonate diethyl ester, bis-(2,6-dicumylphenyl)pentaerythritol diphosphite, 2,2-methylenebis(4,6-di-t-butylphenyl)octyl phosphite, tris(mono- and di-nonylphenyl mixed phosphite), bis(2,4-di-t-butylphenyl)pentaerythritol diphosphite, bis(2,6-di-t-butyl-4-methoxycarbonylethyl-phenyl)pentaerythritol diphosphite, and bis(2,6-di-t-butyl-4-octadecyloxycarbonylethylphenyl)pentaerythritol diphosphite.

Examples of the thioether-based antioxidants include dilauryl-3,3′-thiodipropionate, bis(2-methyl-4-(3-n-dodecyl)thiopropionyloxy)-5-t-butylphenyl)sulfide, distearyl-3,3′-thiodipropionate, and pentaerythritol-tetrakis(3-lauryl)thiopropionate.

### (Filler)

The negative-type photosensitive resin composition according to the present embodiment may further contain a filler. As the filler, an appropriate filling material can be selected according to the mechanical characteristics and thermal characteristics required for a resin film formed from the negative-type photosensitive resin composition.

Specific examples of the fillers include inorganic fillers and organic fillers.

Specific examples of the above-mentioned inorganic fillers include silica such as fused and crushed silica, fused spherical silica, crystalline silica, secondary aggregate silica, and fine powder silica; metal compounds such as alumina, silicon nitride, aluminum nitride, boron nitride, titanium oxide, silicon carbide, aluminum hydroxide, magnesium hydroxide, and titanium white; talc; clay; mica; and glass fibers. As the inorganic filler, one of the above-mentioned specific examples can be used, or two or more thereof can be used in combination.

Specific examples of the organic fillers include organosilicone powders and polyethylene powders. As the organic filler, one of the above-mentioned specific examples can be used, or two or more thereof can be used in combination.

### (Preparation of Negative-Type Photosensitive Resin Composition)

A method for preparing the negative-type photosensitive resin composition of the present embodiment is not limited, and known methods can be used according to the components contained in the negative-type photosensitive resin composition.

For example, the preparation can be performed by mixing and dissolving each of the above-mentioned components in a solvent.

### (Cured Film)

The negative-type photosensitive resin composition according to the present embodiment is used as follows: the negative-type photosensitive resin composition is applied to a surface containing a metal such as Al or Cu; subsequently, drying is performed by pre-baking to form a resin film; subsequently, the resin film is patterned into a desired shape by exposure and development; and subsequently, the resin film is cured by a heat treatment to form a cured film.

Furthermore, when manufacturing the above-mentioned permanent film, as the pre-baking condition, the heat treatment can be performed at a temperature equal to or higher than 90° C. and equal to or lower than 130° C. for equal to or longer than 30 seconds and equal to or shorter than 1 hour, for example. Furthermore, regarding the heat treatment condition, for example, the heat treatment can be performed at a temperature equal to or higher than 150° C. and equal to or lower than 250° C. for equal to or longer than 30 minutes and equal to or shorter than 10 hours, and preferably, the heat treatment can be performed at about 170° C. for 1 to 6 hours.

In a film obtained from the negative-type photosensitive resin composition of the present embodiment, a maximum value of an elongation percentage measured by a tensile test using a TENSILON tester is 15% to 200%, preferably 20% to 150%, and an average value thereof is 10% to 150%, preferably 15% to 120%.

In the film obtained from the negative-type photosensitive resin composition of the present embodiment, a tensile strength measured by a tensile test using a TENSILON tester is preferably equal to or more than 20 MPa, and more preferably 30 to 300 MPa.

In addition, since the negative-type photosensitive resin composition of the present embodiment contains the negative-type photosensitive polymer (A) having excellent hydrolysis resistance, even after carrying out a HAST test (unsaturated pressurized steam test) for 96 hours at a temperature of 130° C. and a relative humidity of 85% RH, the rate of decrease in the elongation percentage (maximum value and average value) expressed by the following expression is equal to or less than 20%, preferably equal to or less than 15%, and more preferably equal to or less than 12%.

[(Elongation percentage before test−elongation percentage after test)/elongation percentage before test)]×100

The negative-type photosensitive resin composition of the present embodiment has excellent low-temperature curing properties.

For example, the glass transition temperature (Tg) of a cured product obtained by curing the negative-type photosensitive resin composition of the present embodiment at 170° C. for 4 hours can be set to equal to or higher than 200° C., preferably equal to or higher than 210° C., and more preferably equal to or higher than 220° C.

Furthermore, the storage elastic modulus E′ at 30° C. of the cured product obtained by curing the negative-type photosensitive resin composition of the present embodiment at 170° C. for 4 hours can be set to equal to or more than 2.0 GPa, preferably equal to or more than 2.5 GPa, and further preferably equal to or more than 3.0 GPa. Furthermore, the storage elastic modulus E′ at 200° C. can be set to equal to or more than 0.5 GPa, preferably equal to or more than 0.7 GPa, and more preferably equal to or more than 0.8 GPa.

The viscosity of the negative-type photosensitive resin composition according to the present embodiment can be appropriately set according to a desired thickness of the resin film. The viscosity of the negative-type photosensitive resin composition can be adjusted by adding a solvent.

A cured product such as a film obtained from the negative-type photosensitive resin composition of the present embodiment has excellent chemical resistance.

Specifically, a film is immersed at 40° C. for 10 minutes in a solution of less than 99% by mass of dimethyl sulfoxide and less than 2% by mass of tetramethylammonium hydroxide, thereafter thoroughly cleaned with isopropyl alcohol, and thereafter air-dried to measure the film thickness after the treatment. The rate of change in the film thickness after the treatment and the film thickness before the treatment is calculated by the following formula, and the loss rate of the film is evaluated.

$$Formula : losss rate ( \% ) of film \{ ( film thickness after immersion - film thickness before immersion ) / film thickness before immersion \times 100 ( \% ) \}$$

The rate of change in the film thickness is preferably equal to or less than 40%, and more preferably equal to or less than 30%. Accordingly, even when the cured film is subjected to a step of being immersed in dimethyl sulfoxide, the film thickness is little reduced. Therefore, the cured film that can maintain functions even after being subjected to such a step can be obtained.

Because cure shrinkage is prevented in the negative-type photosensitive resin composition of the present embodiment, in a case where the film is prepared by spin coating a silicon wafer surface such that the film thickness after drying is 10 μm to perform pre-baking at 120° C. for 3 minutes, thereafter performing exposure to 600 mJ/cm² using a high-pressure mercury lamp, and thereafter performing a heat treatment at 170° C. for 120 minutes in a nitrogen atmosphere, the cure shrinkage ratio calculated from the following formula with the film thickness after the above-mentioned pre-baking as a film thickness A and the film thickness after the above-mentioned heat treatment as a film thickness B can be set to preferably equal to or less than 12%, and more preferably equal to or less than 10%.

$$Formula : cure shrinkage ratio [ \% ] = \{ ( film thickness A - film thickness B ) / film thickness A \} \times 100$$

The negative-type photosensitive resin composition of the present embodiment has high heat resistance, and thus in the obtained film, a weight loss temperature (Td5) measured by thermogravimetry-differential thermal analysis can be set to equal to or higher than 200° C., and preferably equal to or higher than 300° C.

The cure shrinkage is prevented in the film formed from the negative-type photosensitive resin composition of the present embodiment, and thus the coefficient of linear thermal expansion (CTE) can be set to equal to or less than 200 ppm/° C., and preferably equal to or less than 100 ppm/° C.

The film formed from the negative-type photosensitive resin composition of the present embodiment has an excellent mechanical strength, and thus an elastic modulus at 25° C. can be set to 1.0 to 5.0 GPa, and preferably 1.5 to 3.0 GPa.

### (Usage)

The negative-type photosensitive resin composition of the present embodiment is used for forming a resin film for a semiconductor device such as a permanent film and a resist. Among these, the negative-type photosensitive resin composition is preferably used for the usage of using a permanent film from the viewpoint of achieving a balance between the enhancement of the adhesiveness of the negative-type photosensitive resin composition after pre-baking to an Al pad and the prevention of the generation of residue of the negative-type photosensitive resin composition at the time of development, from the viewpoint of enhancing the adhesiveness of the cured film of the negative-type photosensitive resin composition after the heat treatment to metal, and from the viewpoint of improving the chemical resistance of the negative-type photosensitive resin composition after the heat treatment.

Furthermore, in the present embodiment, the resin film includes the cured film of the negative-type photosensitive resin composition. In other words, the resin film according to the present embodiment is obtained by curing the negative-type photosensitive resin composition.

The above-mentioned permanent film is composed of a resin film obtained by pre-baking, exposing, and developing the negative-type photosensitive resin composition to perform patterning into a desired shape, and thereafter curing by a heat treatment. The permanent film can be used as a protective film, an interlayer film, a dam material, and the like for a semiconductor device.

The above-mentioned resist is composed of a resin film obtained by applying the negative-type photosensitive resin composition by a method such as spin coating, roll coating, flow coating, dip coating, spray coating, and doctor coating to a target to be masked by the resist, and removing a solvent from the negative-type photosensitive resin composition.

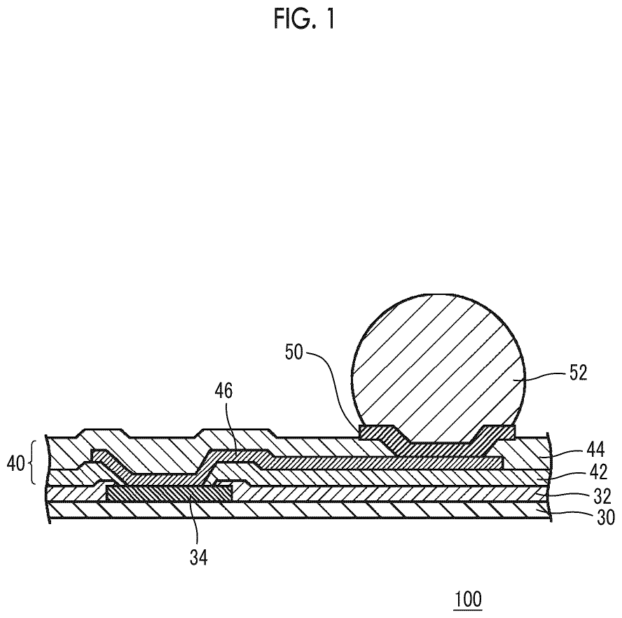

FIG. 1 shows an example of a semiconductor device according to the present embodiment.

A semiconductor device 100 according to the present embodiment can be a semiconductor device having the above-mentioned resin film. Specifically, in the semiconductor device 100, one or more of the group consisting of a passivation film 32, an insulating layer 42, and an insulating layer 44 can be formed from the resin film including the cured product of the present embodiment. The resin film is preferably the above-mentioned permanent film.

The semiconductor device 100 is a semiconductor chip, for example. In this case, a semiconductor package can be obtained by mounting the semiconductor device 100 on a wiring substrate through a bump 52, for example.

The semiconductor device 100 has a semiconductor substrate having a semiconductor element such as a transistor, and a multilayered wiring layer (not shown in the drawing) provided on the semiconductor substrate. The uppermost layer of the multilayered wiring layer having an insulating interlayer 30, and an uppermost layer wiring 34 provided on the insulating interlayer 30. The uppermost layer wiring 34 is composed of aluminum Al, for example. A passivation film 32 is provided on the insulating interlayer 30 and the uppermost layer wiring 34. A part of the passivation film 32 has an opening through which the uppermost layer wiring 34 is exposed.

A re-distribution layer 40 is provided on the passivation film 32. The re-distribution layer 40 has an insulating layer 42 provided on the passivation film 32, a re-distribution 46 provided on the insulating layer 42, and an insulating layer 44 provided on the insulating layer 42 and the re-distribution 46. An opening connected to the uppermost layer wiring 34 is formed in the insulating layer 42. The re-distribution 46 is formed on the insulating layer 42 and in the opening provided in the insulating layer 42, and is connected to the uppermost layer wiring 34. The insulating layer 44 has an opening connected to the re-distribution 46.

The bump 52 is formed in the opening provided in the insulating layer 44 through an Under Bump Metallurgy (UBM)) layer 50, for example. The semiconductor device 100 is connected to a wiring substrate or the like through the bump 52, for example.

Although the embodiments of the present invention have been described above, these are examples of the present invention, and various configurations other than the above-mentioned description can be adopted within a range not impairing the effects of the present invention.

### EXAMPLES

Hereinafter, the present invention will be described in more detail with reference to examples, but the present invention is not limited thereto.

The following compounds were used in the examples.

4,4-Diamino-3,3-diethyl-5,5-dimethyldiphenylmethane (hereinafter also referred to as MED-J) represented by the following formula.

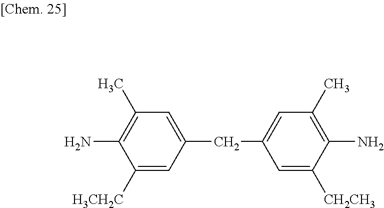

A mixture (hereinafter also referred to as TMDA) of 1-(4-aminophenyl)-1,3,3-trimethylphenylindan-6-amine and 1-(4-aminophenyl)-1,3,3-trimethylphenylindan-5-amine represented by the following formula.

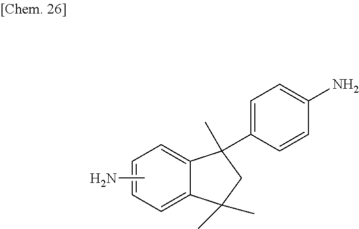

9,9-Bis(3-methyl-4-aminophenyl)fluorene (hereinafter also referred to as BTFL) represented by the following formula.

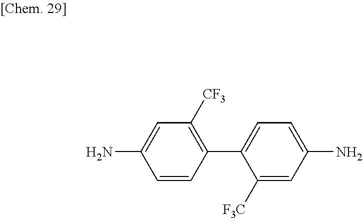 [SMILES: Nc1ccc(-c2ccc(N)cc2C(F)(F)F)c(C(F)(F)F)c1]

4,4′-(Hexafluoroisopropylidene)bis[(4-aminophenoxy)benzene](hereinafter also referred to as HFBAPP) represented by the following formula.

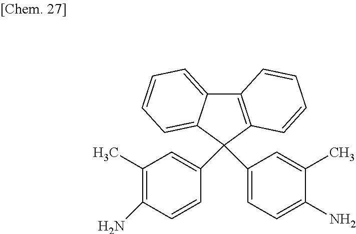

4,4′-Diamino-2,2′-bis(trifluoromethyl)biphenyl (hereinafter also referred to as TFMB) represented by the following formula.

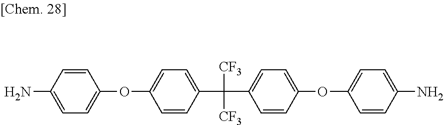 [SMILES: Nc1ccc(Oc2ccc(C(c3ccc(Oc4ccc(N)cc4)cc3)(C(F)(F)F)C(F)(F)F)cc2)cc1]

4-[4-(1,3-Dioxoisobenzofuran-5-ylcarbonyloxy)-2,3,5-trimethylphenyl]-2,3,6-trimethylphenyl 1,3-dioxoisobenzofuran-5-carboxylate (hereinafter also referred to as TMPBP-TME) represented by the following formula.

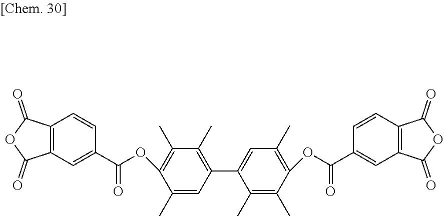 [SMILES: Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O]

1,4-Bis(3,4-dicarboxyphenoxy)benzene dianhydride (hereinafter also referred to as HQDA) represented by the following formula.

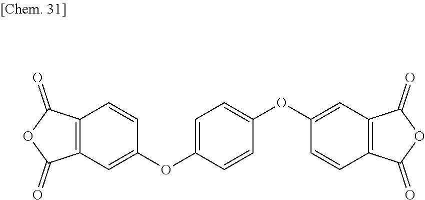 [SMILES: O=C1OC(=O)c2cc(Oc3ccc(Oc4ccc5c(c4)C(=O)OC5=O)cc3)ccc21]

4,4′-(Hexafluoroisopropylidene)diphthalic anhydride (hereinafter also referred to as 6FDA) represented by the following formula.

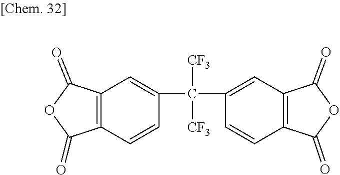 [SMILES: O=C1OC(=O)c2cc(C(c3ccc4c(c3)C(=O)OC4=O)(C(F)(F)F)C(F)(F)F)ccc21]

### Example 1

First, 43.99 g (155.8 mmol) of MED-J and 89.22 g (144.2 mmol) of TMPBP-TME were put into a reaction container having an appropriate size and equipped with a stirrer and a cooling pipe. Thereafter, 399.64 g of γ-butyrolactone (hereinafter also referred to as GBL) was added to the reaction container.

After ventilation with nitrogen for 10 minutes, the temperature was raised to 60° C. while stirring to cause a reaction for 1 hour. A solution was preliminarily created by dissolving 8.73 g (69.2 mmol) of dimethylmaleic anhydride in 26.19 g of gamma-butyrolactone. This solution was put into the reaction container to further cause a reaction for 30 minutes. A reaction was further caused at 175° C. for 3 hours to produce a polymerization solution in which a diamine and an acid anhydride were polymerized and the terminals were blocked.

The obtained polymerization solution was diluted with tetrahydrofuran to produce a diluted solution. Subsequently, the diluted solution was added dropwise to a methanol solution to precipitate a white solid. The obtained white solid was recovered and vacuum-dried at a temperature of 80° C. to obtain 125.88 g of a polymer.

When GPC measurement of the polymer was performed, the weight-average molecular weight Mw was 74,000, the polydispersity (weight-average molecular weight Mw/number-average molecular weight Mn) was 2.62, and the terminal blocking rate was 65%.

The obtained polymer partially had a repeating unit represented by the following formula and had a dimethylmaleimide group at the terminal.

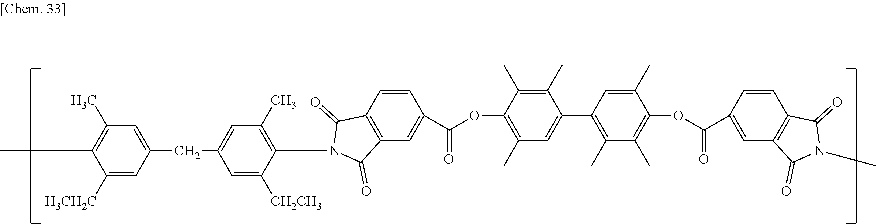

### Examples 2 to 4

For Examples 2 to 4, synthesis was performed in the same technique as in Example 1 except under the conditions shown in Table 1. The table shows the obtained Mw, PDI, and terminal blocking rate.

The polymers obtained in Examples 2 to 4 partially had a repeating unit represented by the following formula and had a dimethylmaleimide group at the terminal.

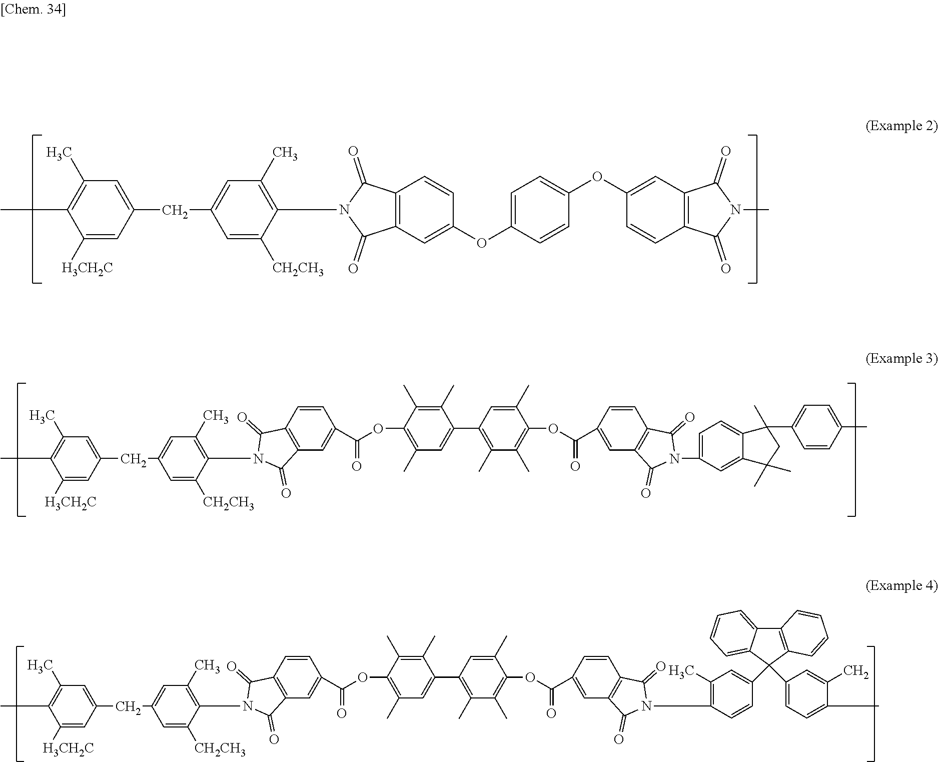

### Comparative Example 11

First, 5.92 g (21.0 mmol) of MED-J, 10.86 g (21.0 mmol) of HFBAPP, and 23.57 g (38.1 mmol) of TMPBP-TME were put into a reaction container having an appropriate size and equipped with a stirrer and a cooling pipe. Thereafter, 121.04 g of γ-butyrolactone (hereinafter also referred to as GBL) was added to the reaction container.

After ventilation with nitrogen for 10 minutes, the temperature was raised to 60° C. while stirring to cause a reaction for 1 hour. A solution was preliminarily created by dissolving 2.88 g (22.9 mmol) of dimethylmaleic anhydride in 8.65 g of gamma-butyrolactone. This solution was put into the reaction container to further cause a reaction for 30 minutes. A reaction was further caused at 175° C. for 3 hours to produce a polymerization solution in which a diamine and an acid anhydride were polymerized and the terminals were blocked.

The obtained polymerization solution was diluted with tetrahydrofuran to produce a diluted solution. Subsequently, the diluted solution was added dropwise to a methanol solution to precipitate a white solid. The obtained white solid was recovered and vacuum-dried at a temperature of 80° C. to obtain 35.42 g of a polymer.

When GPC measurement of the polymer was performed, the weight-average molecular weight Mw was 55,600, the polydispersity (weight-average molecular weight Mw/number-average molecular weight Mn) was 2.33, and the terminal blocking rate was 75%.

The obtained polymer partially had a repeating unit represented by the following formula and had a dimethylmaleimide group at the terminal.

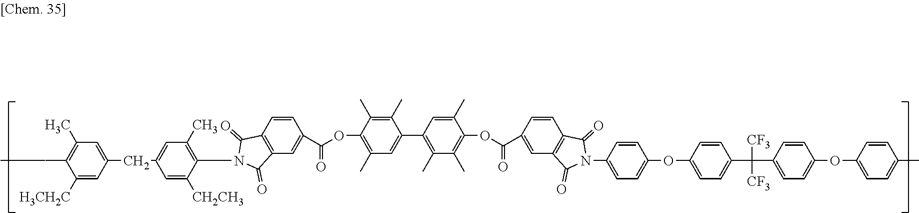

### Comparative Example 2

First, 7.33 g (26.0 mmol) of MED-J, 8.31 g (26.0 mmol) of TFMB, and 29.74 g (48.1 mmol) of TMPBP-TME were put into a reaction container having an appropriate size and equipped with a stirrer and a cooling pipe. Thereafter, 136.16 g of γ-butyrolactone (hereinafter also referred to as GBL) was added to the reaction container.

After ventilation with nitrogen for 10 minutes, the temperature was raised to 60° C. while stirring to cause a reaction for 1 hour. A solution was preliminarily created by dissolving 2.91 g (23.1 mmol) of dimethylmaleic anhydride in 8.73 g of gamma-butyrolactone. This solution was put into the reaction container to further cause a reaction for 30 minutes. A reaction was further caused at 175° C. for 3 hours to produce a polymerization solution in which a diamine and an acid anhydride were polymerized and the terminals were blocked.

The obtained polymerization solution was diluted with tetrahydrofuran to produce a diluted solution. Subsequently, the diluted solution was added dropwise to a methanol solution to precipitate a white solid. The obtained white solid was recovered and vacuum-dried at a temperature of 80° C. to obtain 35.44 g of a polymer.

When GPC measurement of the polymer was performed, the weight-average molecular weight Mw was 69,500, the polydispersity (weight-average molecular weight Mw/number-average molecular weight Mn) was 2.51, and the terminal blocking rate was 65%.

The obtained polymer partially had a repeating unit represented by the following formula and had a dimethylmaleimide group at the terminal.

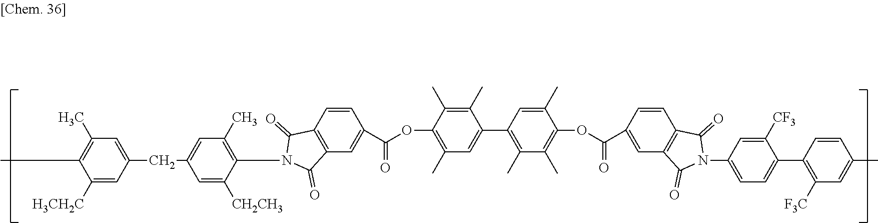

### Comparative Examples 3 to 5

For Comparative Examples 3 to 5, synthesis was performed in the same technique as in Example 1 except under the conditions shown in Table 1. Table 1 shows the obtained Mw and Mw/Mn.

### [Average Value of Positive Electric Charges (δ+) of Two Carbonyl Carbons of Imide Ring]

The average value of the positive electric charges (δ+) of two carbonyl carbons of the imide ring of the negative-type photosensitive polymer obtained in Example 1 was calculated as follows.

The negative-type photosensitive polymer of Example 1 had a structural unit (A) of Chemical Formula (A) below.

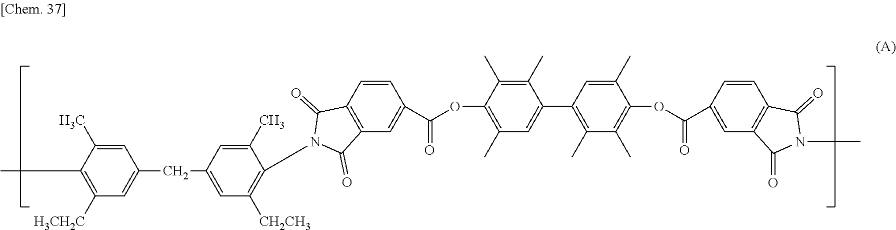

In this case, a compound (A′) represented by Chemical Formula (A′) below was measured by a charge equilibration method using soft HSPiP (ver. 5.3), and δ+ of two carbonyl carbons (*1, *2) of the imide ring contained in the above-mentioned compound (A′) was averaged to obtain an average value.

The calculation was performed in the same manner for the other examples and comparative examples.

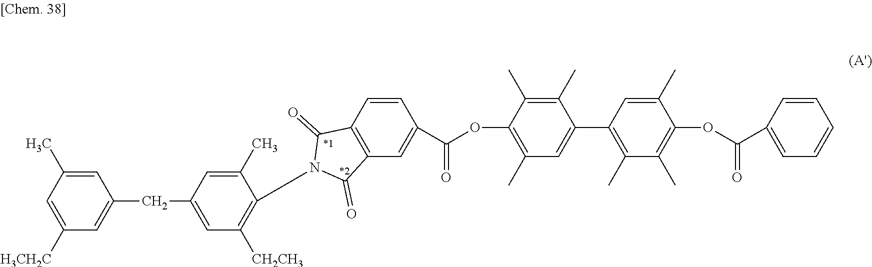

### [Measurement of Terminal Blocking Rate]

The solution after the reaction was measured by gas chromatography, and in a case where it was assumed that all of the dimethylmaleic anhydride consumed in the reaction was bonded to the polymer terminal, a ratio of the actual consumption amount to the theoretical consumption amount of dimethylmaleic anhydride was defined as the blocking rate of the polymer terminals by dimethylmaleic anhydride.

### [Solubility in Organic Solvent]

The solubility of the negative-type photosensitive polymers obtained in Examples 1 to 3 and Comparative Examples 1 and 2 in γ-butyrolactone (GBL) and cyclopentanone was evaluated according to the following criteria. Table 1 shows the results.

### (Evaluation Criteria of Solubility)

∘: equal to or more than 5% by mass of the polymer was dissolved.
Δ: 1% to 5% by mass of the polymer was dissolved.
x: the solubility of the polymer was less than 1% by mass.

### [Hydrolysis Resistance]

The reduction rates of the weight-average molecular weights of the negative-type photosensitive polymers obtained in the examples and the comparative examples were measured under the following condition. Table 1 shows the results.

### (Condition (No Addition of Triethylamine))

When 400 parts by mass of γ-butyrolactone, 200 parts by mass of 4-methyltetrahydropyran, and 50 parts by mass of water were added to 100 parts by mass of the negative-type photosensitive polymer to stir at 100° C. for 6 hours, calculation was carried out by the following expression.

Expression: [(weight-average molecular weight before test−weight-average molecular weight after test)/weight-average molecular weight before test]×100

$$Expression : [ ( weight - average molecular weight before test - weight - average molecular weight after test ) / weight - average molecular weight before test ] \times 100$$

### (Condition (Addition of Triethylamine))

When 10 parts by mass of triethylamine, 400 parts by mass of γ-butyrolactone, 200 parts by mass of 4-methyltetrahydropyran, and 50 parts by mass of water were added to 100 parts by mass of the negative-type photosensitive polymer to stir at 100° C. for 6 hours, calculation was carried out by the following expression.

$$Expression : [ ( weight - average molecular weight before test - weight - average molecular weight after test ) / weight - average molecular weight before test ] \times 100$$

### [Elongation Percentage]

A silicon wafer surface was spin-coated with the polymer solutions (100 parts by mass of the polymer) obtained in the examples and the comparative examples to perform pre-baking at 120° C. for 4 minutes. Thereafter, a heat treatment was performed at 200° C. for 120 minutes under nitrogen to prepare a film.

A tensile test (stretching speed: 5 mm/minute) was performed in an atmosphere of 23° C. on a test piece (6.5 mm×60 mm×10 μm thick) cut out from the obtained film. The tensile test was performed using a tension tester (TENSILON RTC-1210A) manufactured by ORIENTEC CO., LTD. Five test pieces were measured to calculate the tensile elongation percentage from a fracture distance and an initial distance, and the maximum value and the average value of the elongation percentage were obtained. Table 1 shows the results.

TABLE 2
Table 1

| | | | | | | Comparative |
|---|---|---|---|---|---|---|
| | | Example 1 | Example 2 | Example 3 | Example 4 | Example 1 |
| Diamine 1 | Type | MED-J | MED-J | MED-J | MED-J | MED-J |
| | Charging molar | 108 | 103 | 51.5 | 51.5 | 55 |
| | ratio | | | | | |
| Diamine 2 | Type | | | TMDA | BTFL | HFBAPP |
| | Charging molar | | | 51.5 | 51.5 | 55 |
| | ratio | | | | | |
| Acid anhydride | Type | TMPBP- | HQDA | TMPBP- | TMPBP- | TMPBP- |
| | | TME | | TME | TME | TME |
| | Charging molar | 100 | 100 | 100 | 100 | 100 |
| | ratio | | | | | |
| Mw | | 74,000 | 63,400 | 77,000 | 82,800 | 55,600 |
| PDI | | 2.30 | 2.83 | 2.07 | 2.10 | 2.33 |
| DMMI introduction rate | | 65% | 79% | 100% | 86% | 75% |
| Average value of δ+ | | 0.087 | 0.086 | 0.090 | 0.089 | 0.096 |
| Solvent solubility | GBL | ◯ | ◯ | ◯ | ◯ | ◯ |
| | Cyclopentanone | ◯ | ◯ | ◯ | ◯ | ◯ |
| Hydrolysis resistance | TEA not added | 4% | 7% | 1% | 2% | 4% |
| (Mw reduction rate) | TEA added | 16% | 26% | 26% | 14% | 55% |
| Elongation (MAX) | | 59% | | | | 72% |
| Elongation (Ave.) | | 22% | | | | 47% |

| | | Comparative | Comparative | Comparative | Comparative |
|---|---|---|---|---|---|
| | | Example 2 | Example 3 | Example 4 | Example 5 |
| Diamine 1 | Type | MED-J | TFMB | TFMB | TFMB |
| | Charging molar | 54 | 102 | 120 | 102 |
| | ratio | | | | |
| Diamine 2 | Type | TFMB | | | |
| | Charging molar | 54 | | | |
| | ratio | | | | |
| Acid anhydride | Type | TMPBP- | 6FDA | TMPBP- | 6FDA |
| | | TME | | TME | |
| | Charging molar | 100 | 100 | 100 | 75 |
| | ratio | | | | |
| Mw | | 69,500 | 81,100 | 29,300 | 39,300 |
| PDI | | 2.51 | 2.24 | 2.22 | 1.81 |
| DMMI introduction rate | | 65% | 83% | — | 76% |
| Average value of δ+ | | 0.105 | 0.122 | 0.110 | 0.119 |
| Solvent solubility | GBL | ◯ | ◯ | ◯ | ◯ |
| | Cyclopentanone | ◯ | ◯ | ◯ | ◯ |
| Hydrolysis resistance | TEA not added | 7% | 50% | 12% | 18% |
| (Mw reduction rate) | TEA added | 52% | 90% | 60% | 75% |
| Elongation (MAX) | | 40% | | | |
| Elongation (Ave.) | | 23% | | | |

As shown in Table 1, in the negative-type photosensitive polymer of the present invention obtained in the examples in which the average value of the positive electric charges (δ+) of two carbonyl carbons of the imide ring was equal to or less than 0.095, it was observed that the solubility in an organic solvent and elongation were excellent, and that because hydrolysis was inhibited, a decrease in the elongation percentage was small, and a reduction in mechanical strength was minimized.

The following compounds were used in the preparation of the negative-type photosensitive resin composition.
Photosensitizing agent: 1-chloro-4-propoxythioxanthone (SPEEDCURE CPTX (trade name) manufactured by Lambson, UK)
Solvent: cyclopentanone

### Synthesis Example 1

### Synthesis of Maleic Acid Anhydride-Modified Norbornene Monomer (DMMIBuNB, 1-[4-(5-2-norbornyl)butyl]-3,4-dimethyl-pyrrole-2,5-dione)

In a 500 mL round-bottomed flask, dimethylmaleic anhydride (42.6 g, 0.34 mol) was dissolved in toluene (300 mL) at room temperature. The solution was put under a nitrogen gas atmosphere to remove oxygen. The reaction flask was placed in an ice bath to prevent excessive heating caused by an exothermic reaction. When the dimethylmaleic anhydride was dissolved, a dropping funnel containing 5-norbornene-2-butylamine (49.6 g, 0.30 mol) was attached to added dropwise a norbornene compound to the reaction flask over 3 hours. The dropping funnel was detached, and a Dean-Stark tube and a reflux condenser were attached to the flask. The solution was heated to reflux in an oil bath set at 125° C., and the reaction product was stirred at that temperature for 18 hours. During this time, about 6 mL of water was recovered in the Dean-Stark tube. The flask was removed from the oil bath and cooled to room temperature. The toluene solvent was removed using an evaporator to obtain a yellow oily substance. The crude product was put to a flash chromatography column (250 g silica gel) and eluted using a solvent mixture of 1.7 liters of cyclohexane/ethyl acetate (95/5 wt ratio). The elution solvent was removed using an evaporator, and thereafter drying was performed under vacuum at 45° C. for 18 hours to obtain 80.4 g (yield of 92.7%) of a desired product. The reaction formula is shown below.

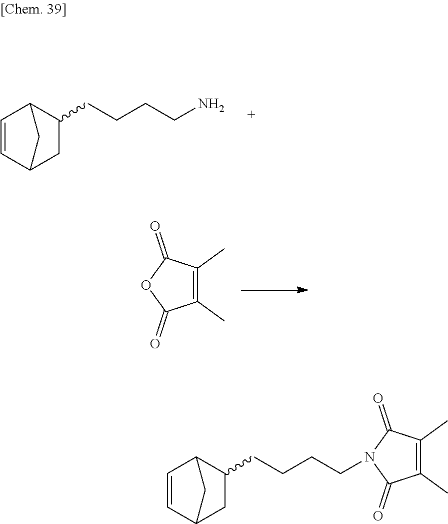

### (Synthesis of Polymer (DMMI-PNB))

24.6 g of 1-[4-(5-2-norbornyl)butyl]-3,4-dimethyl-pyrrole-2,5-dione) obtained by the above-mentioned method, 3.1 g of triethylsilane, 13.5 g of toluene, and 4.5 g of ethyl acetate were put into a nitrogen-substituted reaction container. Furthermore, a mixed solution was produced by adding 3.8 g of toluene and 1.3 g of ethyl acetate to 0.065 g of [Pd(P (iPr)3)2 (OCOCH3) (NCCH3)]tetrakis(pentafluorophenyl)borate at a concentration of 2.1 wt %, and 0.043 g of N,N-dimethylanilinium tetrakis(pentafluorophenyl)borate. The mixed solution was added to a reaction container to cause a reaction at 70° C. for 3 hours, and thereby a polymer solution was obtained. The conversion rate to a polymer was 91%. In addition, the weight-average molecular weight of the obtained polymer was 6,700, and the molecular weight distribution was 1.89.

The prepared polymer solution was diluted with tetrahydrofuran, redeposited with methanol, filtered, and thereafter vacuum-dried at 50° C. to obtain 18 g of a polymer (DMMI-PNB).

### Example 5

### (Preparation of Negative-Type Photosensitive Resin Composition)

The polymer solution of Example 1 (polymer DMMI-PI, 12.0 parts by mass), the polymer (DMMI-PNB) of Synthesis Example 1, and the components shown in Table 2 were mixed in the amounts shown in Table 2 to prepare a photosensitive resin composition.

A silicon wafer surface was spin-coated with the obtained negative-type photosensitive resin composition such that the film thickness after drying was 10 μm to perform pre-baking at 120° C. for 4 minutes. Thereafter, exposure to 1,500 mJ/cm² was performed using a high-pressure mercury lamp. Thereafter, a heat treatment was performed at 200° C. for 120 minutes in a nitrogen atmosphere to prepare a film.

### Comparative Example 6

A photosensitive resin composition was prepared in the same manner as in Example 5 except that the polymer solution of Comparative Example 1 (polymer DMMI-PI 12.0 parts by mass) was used, and then a film was prepared from the photosensitive resin composition.

### [Glass Transition Temperature (Tg)]

A test piece of 8 mm×40 mm was cut out from the film obtained in Example 5. Dynamic mechanical analysis was performed on this test piece at a temperature rising rate of 5° C./minute and a frequency of 1 Hz using dynamic mechanical analysis (DMA device, manufactured by TA Instruments, Q800). A temperature at which a loss tangent tan δ was a maximum value was measured as a glass transition temperature.

### [Elongation Percentage]

A tensile test (stretching speed: 5 mm/minute) was performed in an atmosphere of 23° C. on test pieces (6.5 mm×60 mm×10 μm thick) cut out from the films obtained in Example 5 and Comparative Example 6. The tensile test was performed using a tension tester (TENSILON RTC-1210A) manufactured by ORIENTEC CO., LTD. Five test pieces were measured, and the stresses at the fracturing point were averaged to obtain a strength. The tensile elongation percentage was calculated from a fracture distance and an initial distance, and the average value and the maximum value of the elongation percentage were obtained.

Furthermore, HAST (unsaturated pressurized steam test) was performed on the above-mentioned test pieces cut out from the films obtained in Example 5 and Comparative Example 6 for 96 hours under the condition at a temperature of 130° C. and a relative humidity of 85% RH. Thereafter, the average value and the maximum value of the elongation percentage were obtained in the same manner as described above.

### (Dielectric Loss Tangent Df)

The photosensitive resin composition of Example 5 was applied onto a substrate, and this application film was dried at 120° C. for 10 minutes. PLA exposure (540 mJ) was performed, and curing was performed at 200° C. for 2 hours in a nitrogen atmosphere to obtain a film having a film thickness of 100 μm. The dielectric loss tangent at 10 GHz of the obtained film was measured by a cavity resonator method.

### [Evaluation Relating to Patterning Characteristics]

Whether the photosensitive resin composition of Example 5 could be sufficiently patterned by exposure and development was confirmed as follows.

The photosensitive resin composition of Example 5 was applied onto an 8-inch silicon wafer using a spin coater. After the application, pre-baking was performed for 4 minutes at 120° C. on a hot plate in the atmosphere to obtain a coating film having a film thickness of about 8.0 μm.

This coating film was irradiated with i-line through a mask in which a via pattern having a width of 20 μm was drawn. For irradiation, an i-line Stepper (manufactured by Nikon Corporation, NSR-4425i) was used.

After exposure, using cyclopentanone as a developing solution, spray development was performed for 120 seconds to dissolve and remove unexposed portions, and thereby a via pattern was obtained.

The cross-section of the obtained via pattern was observed using a tabletop-SEM. The width at an intermediate height of the bottom surface of the via pattern and the opening was defined as a via width, which was evaluated according to the following criteria.

Favorable patterning properties: a via pattern of 20 μm was opened.

Poor patterning properties: a via pattern of 20 μm was not opened.

The coating film obtained from the photosensitive resin composition of Example 5 had favorable patterning properties.

TABLE 2

| | | | | Comparative |
|---|---|---|---|---|
| | | Unit | Example 5 | Example 6 |
| Polymer | DMMI-PI | Part by | 12.0 | 12.0 |
| Crosslinking agent | DMMI-PNB | mass | 8.0 | 8.0 |
| Photosensi- | Photosensi- | | 0.2 | 0.2 |
| tizing agent | tizing agent | | | |
| Solvent | Solvent | | 79.8 | 79.8 |
| Tg | | ° C. | 240 | |
| Elongation (MAX) | Before uHAST | % | 61 | 91 |
| Elongation (MAX) | After uHAST | % | 64 | 61 |
| Elongation (Ave.) | Before uHAST | % | 31 | 70 |
| Elongation (Ave.) | After uHAST | % | 32 | 31 |

| | | |
|---|---|---|
| Dielectric loss tangent | GPa | 0.004 |
| (10 GHz) | | |
| Patterning characteristics | | Favorable |

As shown in Table 2, in the film obtained from the negative-type photosensitive resin composition containing the negative-type photosensitive polymer of the present invention in which the average value of the positive electric charges (δ+) of two carbonyl carbons of the imide ring was equal to or less than 0.095, it was clarified that a low dielectric dissipation factor was excellent and elongation was also excellent, and it was also clarified that mechanical strength was excellent even after the HAST test since the negative-type photosensitive polymer having excellent hydrolysis resistance was contained. In addition, it was confirmed that the patterning properties were also favorable, and suitable use as a negative-type photosensitive resin composition was possible.

The present application claims priority based on Japanese Patent Application No. 2021-105687 filed on Jun. 25, 2021 and Japanese Patent Application No. 2022-019325 filed on Feb. 10, 2022, the disclosure of which is incorporated herein in its entirety.

### REFERENCE SIGNS LIST

100 semiconductor device
30 insulating interlayer
32 passivation film
34 uppermost layer wiring
40 re-distribution layer
42 insulating layer
44 insulating layer
46 re-distribution
50 UBM layer
52 bump

What is claim is:

1. A solvent-soluble negative-type photosensitive polymer which has a structural unit containing an imide ring, the negative-type photosensitive polymer comprising, at at least one of both terminals,
a group represented by General Formula (t),
wherein an average value of positive electric charges (δ+) of two carbonyl carbons of the imide ring is equal to or less than 0.095 as calculated by a charge equilibration method, 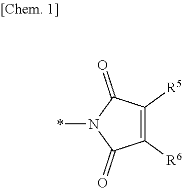
(in General Formula (t), R⁵ and R⁶ each independently represent a hydrogen atom or an alkyl group having 1 to 3 carbon atoms, provided that at least one is an alkyl group having 1 to 3 carbon atoms; and * represents a bonding site).

2. The negative-type photosensitive polymer according to claim 1,
wherein a fluorine atom is not contained in a molecular structure.

3. The negative-type photosensitive polymer according to claim 1,
wherein the structural unit is represented by General Formula (1), 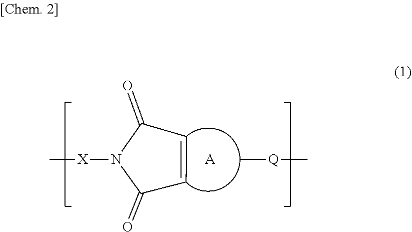
(in General Formula (1), X represents a divalent organic group including an aromatic group; A represents a ring structure having two carbons of the imide ring; and Q represents a divalent organic group).

4. The negative-type photosensitive polymer according to claim 3, further comprising
an asymmetrical electron-donating group at two ortho positions with respect to a carbon atom bonded to a nitrogen atom in General Formula (1),
wherein the aromatic group included in the divalent organic group as X in General Formula (1) is bonded to the nitrogen atom.

5. The negative-type photosensitive polymer according to claim 3,
wherein X in General Formula (1) is a divalent group represented by General Formula (1a) or General Formula (1 b), 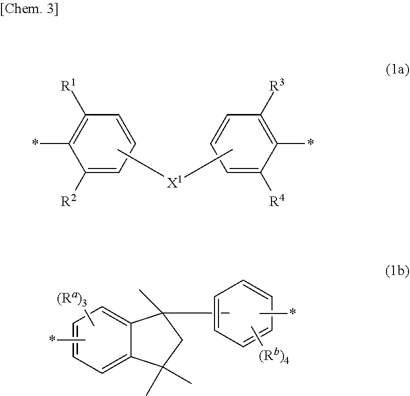
(in General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups; X¹ represents a single bond, —SO₂—, —C(═O)—, a linear or branched alkylene group having 1 to 5 carbon atoms, or a fluorenylene group; and * represents a bonding site, and
in General Formula (1 b), R^{a} and R^{b} each independently represent a hydrogen atom, an alkyl group having 1 to 3 carbon atoms, or an alkoxy group having 1 to 3 carbon atoms, provided that a plurality of R^{a}'s may be the same as or different from each other, and a plurality of R^{b}'s may be the same as or different from each other; and * represents a bonding site).

6. The negative-type photosensitive polymer according to claim 3,
wherein A in General Formula (1) is an aromatic ring.

7. The negative-type photosensitive polymer according to claim 3,
wherein Q in General Formula (1) is a divalent group containing an imide ring.

8. The negative-type photosensitive polymer according to claim 5,
wherein the structural unit represented by General Formula (1) includes a structural unit represented by General Formula (1-1), 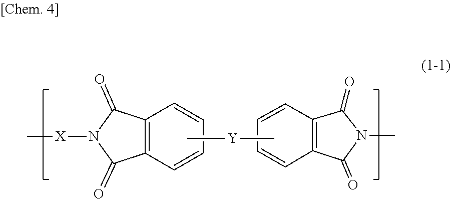
(in General Formula (1-1), X is the divalent group represented by General Formula (1a) or General Formula (1 b); and Y is a divalent organic group).

9. The negative-type photosensitive polymer according to claim 8,
wherein Y in General Formula (1-1) is a divalent organic group selected from General Formula (a1-1), General Formula (a1-2), General Formula (a1-3), and General Formula (a1-4), 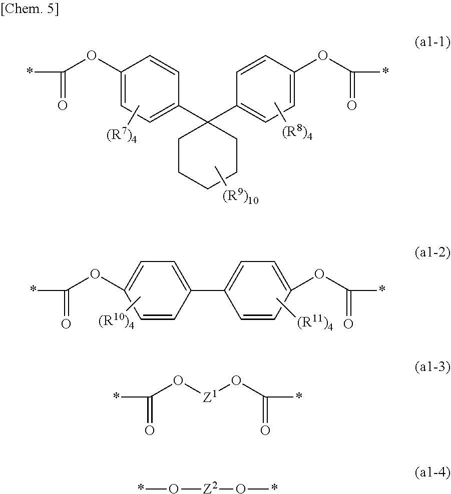
(in General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other; R⁹ represents a hydrogen atom, an alkyl group having 1 to 3 carbon atoms, or an alkoxy group having 1 to 3 carbon atoms, provided that a plurality of R⁹'s may be the same as or different from each other; and * represents a bonding site,
in General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other; and * represents a bonding site,
in General Formula (a1-3), Z¹ represents an alkylene group having 1 to 5 carbon atoms or a divalent aromatic group; and * represents a bonding site, and
in General Formula (a1-4), Z² represents a divalent aromatic group; and * represents a bonding site).

10. The negative-type photosensitive polymer according to claim 8, further comprising, at at least one of both of the terminals,
a group represented by General Formula (t-1), 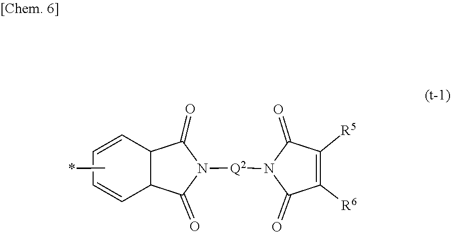
(in General Formula (t-1), R⁵ and R⁶ each independently represent a hydrogen atom or an alkyl group having 1 to 3 carbon atoms, provided that at least one is an alkyl group having 1 to 3 carbon atoms; Q² represents a divalent organic group; and * represents a bonding site).

11. The negative-type photosensitive polymer according to claim 1,
wherein equal to or more than 5% by mass of the negative-type photosensitive polymer is dissolved in a solvent selected from N-methyl-2-pyrrolidone, N-ethyl-2-pyrrolidone, γ-butyrolactone (GBL), and cyclopentanone.

12. The negative-type photosensitive polymer according to claim 1,
wherein equal to or more than 5% by mass of the negative-type photosensitive polymer is dissolved in cyclopentanone.

13. The negative-type photosensitive polymer according to claim 1,
wherein a reduction rate of a weight-average molecular weight measured under the following condition is equal to or less than 15%,
(condition)
when 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression,
expression: [(weight-average molecular weight before test−weight-average molecular weight after test)/weight-average molecular weight before test]×100.

14. A polymer solution comprising
the negative-type photosensitive polymer according to claim 1.

15. A negative-type photosensitive resin composition comprising:
(A) the negative-type photosensitive polymer according to claim 1;
(B) a crosslinking agent (B) (excluding the polyimide (A)) having a substituted or unsubstituted maleimide group; and
(C) a photosensitizer.

16. The negative-type photosensitive resin composition according to claim 15,
wherein the crosslinking agent (B) has a structural unit represented by General Formula (b), 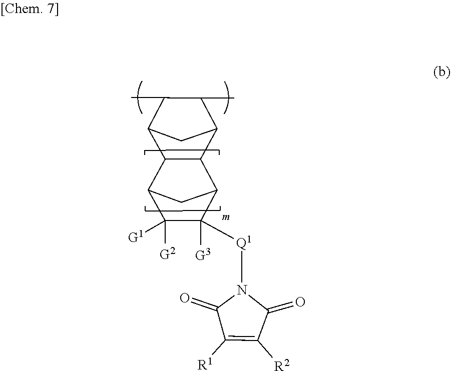
(in General Formula (b), R¹ and R² each independently represent a hydrogen atom or an alkyl group having 1 to 3 carbon atoms; Q¹ represents a single bond or a divalent organic group; G¹, G², and G³ each independently represent a hydrogen atom or a substituted or unsubstituted hydrocarbon group having 1 to 30 carbon atoms; and m is 0, 1, or 2).

17. The negative-type photosensitive resin composition according to claim 16,
wherein the divalent organic group as Q¹ is an alkylene group having 1 to 8 carbon atoms or a (poly)alkylene glycol chain.

18. A cured film comprising
a cured product of the negative-type photosensitive resin composition according to claim 15.

19. A semiconductor device comprising
a resin film including a cured product of the negative-type photosensitive resin composition according to claim 15.
